(19) United States
(12) Patent Application Publication
(10) Pub. No.: US 2019/0259802 A1
(43) Pub. Date: Aug. 22, 2019

(54) ACTIVE MATRIX SUBSTRATE, IMAGING PANEL INCLUDING SAME AND PRODUCING METHOD THEREOF

(71) Applicant: SHARP KABUSHIKI KAISHA, Sakai City (JP)

(72) Inventor: KATSUNORI MISAKI, Yonago-shi (JP)

(21) Appl. No.: 16/277,932

(22) Filed: Feb. 15, 2019

(30) Foreign Application Priority Data
Feb. 16, 2018 (JP) 2018-026462

(51) Int. Cl. H01L 27/146; H01L 27/12; G01T 1/20

(52) U.S. Cl. CPC H01L 27/14663; H01L 27/124; H01L 31/115; G01T 1/2018; H01L 27/127

(57) ABSTRACT

An active matrix substrate 1 has a plurality of detection circuitry. The detection circuitry includes a photoelectric conversion layer 15, a first electrode 14a and a second electrode 14b which interpose the photoelectric conversion layer 15 therebetween, a first insulating film 105, and a second insulating film 106. The first insulating film 105 covers a part of the photoelectric conversion layer 15, and has an opening 105a on the photoelectric conversion layer 15. The second insulating film 106 is provided on the first insulating film 105, and has an opening 106a having a width greater than that of the first insulating film 105. The second electrode 14b is in contact with the photoelectric conversion layer 15 in the first opening 105a, and is in contact with the first insulating film 105 and the second insulating film 106.

### TECHNICAL FIELD

The present invention relates to an active matrix substrate, an imaging panel including the same, and a method for producing the same.

### BACKGROUND ART

Conventionally, an X-ray imaging device is known that includes thin film transistors (also referred to as “TFTs”) in a plurality of areas arranged in matrix (hereinafter referred to as pixel portions), and picks up an image of irradiated X-rays with a plurality of pixel portions. In such an X-ray imaging device, for example, p-intrinsic-n (PIN) photodiodes are used as photoelectric conversion elements that convert irradiated X-rays into charges. The converted charges are read out by causing the TFTs of the respective pixels portions to operate. With the charges being read out in this way, an X-ray image is obtained.

Patent Document 1 shown below discloses such an X-ray imaging device. In the configuration disclosed in Patent Document 1, a photoelectric conversion layer and an upper electrode layer formed on an array substrate of the X-ray imaging device are etched by using the same resist mask so that the photoelectric conversion layers and the upper electrodes are simultaneously formed in island patterns.

### PRIOR ART DOCUMENT

Patent Document
Patent Document 1: JP-A-2014-078651

### SUMMARY OF THE INVENTION

Incidentally, a native oxide film adhering to the surface of the PIN photodiode is removed by using hydrofluoric acid in some cases. In a case where a photoelectric conversion layer and an upper electrode are simultaneously formed as is the case with Patent Document 1, when a native oxide film and the like adhering to side wall of the photoelectric conversion layer are removed with use of hydrofluoric acid, not only the photoelectric conversion layer but also the upper electrode are exposed to the hydrofluoric acid. As a result, metal ions of the upper electrode adhere to the side walls of the photoelectric conversion layer, which cause off-leakage current of the photoelectric conversion layer to increase.

Alternatively, for example, the following configuration can be proposed: a first protection film that has an opening on the photoelectric conversion layer and covers the side surfaces of the photoelectric conversion layer, and a second protection film on the first protection film, are provided, and the upper electrode is in contact with the photoelectric conversion layer through the openings in the first protection film and the second protection film. In this case, if the first protection film and the second protection film are formed and thereafter the surface of the photoelectric conversion layer is cleaned with use of hydrofluoric acid before the upper electrode is formed, end portions of the first protection film on the first protection film are etched with hydrofluoric acid toward an inner side with respect to the second protection film, which results in that the second protection film is jutted out toward an inner side of the photoelectric conversion layer. If the upper electrode is formed in this state, the upper electrode tends to have disconnections at step portions of the first protection film and the second protection film, which results in that contact defects occur between the upper electrode and the photoelectric conversion layer.

It is an object of the present invention to provide a technique with which contact defects are prevented from occurring between the photoelectric conversion layers and the electrodes.

An active matrix substrate according to the present invention is an active matrix substrate having a plurality of detection circuitry are arranged in matrix. The detection circuitry includes: a photoelectric conversion layer; a first electrode provided on a first surface of the photoelectric conversion layer; a second electrode provided on a second surface of the photoelectric conversion layer, the second surface being on a side opposite to the side of the first surface; a first insulating film that covers an end portion of the second surface and a side surface of the photoelectric conversion layer, and has a first opening on the second surface; and a second insulating film that overlaps with the first insulating film, and has a second opening that has an opening width greater than that of the first opening, the second opening being on the second surface. The second electrode is in contact with the second surface in the first opening, and is in contact with the first insulating film and the second insulating film.

With the present invention, contact defects can be prevented from occurring between the photoelectric conversion layers and the electrodes.

### BRIEF DESCRIPTION OF DRAWINGS

FIG. 1 schematically illustrates an X-ray imaging device in Embodiment 1.

FIG. 2 schematically illustrates a schematic configuration of the active matrix substrate shown in FIG. 1.

FIG. 3 is an enlarged plan view showing one pixel portion of the active matrix substrate shown in FIG. 2.

FIG. 4 is a cross-sectional view of the pixel shown in FIG. 3, taken along line A-A.

FIG. 5 is an enlarged view showing a portion in the broken-line frame in FIG. 4.

FIG. 6A is a cross-sectional view showing a step in a process for producing the active matrix substrate shown in FIG. 4, the step being a step of forming a first insulating film, in a state in which a gate insulating film and a TFT are formed on a substrate.

FIG. 6B is a cross-sectional view showing a step of patterning the first insulating film shown in FIG. 6A so as to form an opening in the first insulating film.

FIG. 6C is a cross-sectional view showing a step of forming a second insulating film shown in FIG. 4.

FIG. 6D is a cross-sectional view showing a step of patterning the second insulating film shown in FIG. 6C so as to form an opening in the second insulating film.

FIG. 6E is a cross-sectional view showing a step of forming a metal film that will become the lower electrode shown in FIG. 4.

FIG. 6F is a cross-sectional view showing a step of patterning the metal film shown in FIG. 6E so as to form the lower electrode.

FIG. 6G is a cross-sectional view showing a step of forming an n-type amorphous semiconductor layer, an intrinsic amorphous semiconductor layer, and a p-type amorphous semiconductor layer that will become the photoelectric conversion layer shown in FIG. 4.

FIG. 6H is a cross-sectional view showing a step of patterning the n-type amorphous semiconductor layer, the intrinsic amorphous semiconductor layer, and the p-type amorphous semiconductor layer shown in FIG. 6G so as to form the photoelectric conversion layer.

FIG. 6I is a cross-sectional view showing a step of forming a third insulating film shown in FIG. 4.

FIG. 6J is a cross-sectional view showing a step of patterning the third insulating film shown in FIG. 6I so as to form an opening in the third insulating film.

FIG. 6K is a cross-sectional view showing a step of forming a fourth insulating film shown in FIG. 4.

FIG. 6L is a cross-sectional view showing a step of patterning the fourth insulating film shown in FIG. 6K so as to form an opening in the fourth insulating film.

FIG. 6M is a cross-sectional view showing a state after the surface of the p-type amorphous semiconductor layer shown in FIG. 6L is cleaned with use of hydrofluoric acid.

FIG. 6N is a cross-sectional view showing a step of forming a transparent conductive film that will become the upper electrode shown in FIG. 4.

FIG. 6O is a cross-sectional view showing a step of patterning the transparent conductive film shown in FIG. 6N so as to form the upper electrode.

FIG. 6P is a cross-sectional view showing a step of forming a metal film that will become the bias line shown in FIG. 4.

FIG. 6Q is a cross-sectional view showing a step of patterning the metal film shown in FIG. 6P so as to form the bias line.

FIG. 6R is a cross-sectional view showing a step of forming a fifth insulating film shown in FIG. 4.

FIG. 6S is a cross-sectional view showing a step of forming a sixth insulating film shown in FIG. 4.

FIG. 7A is an enlarged cross-sectional view showing the third insulating film and the p-type amorphous semiconductor layer after the third insulating film is etched with use of hydrofluoric acid.

FIG. 7B is an enlarged cross-sectional view showing the p-type amorphous semiconductor layer and the third insulating film after the surface of the p-type amorphous semiconductor layer is cleaned with use of hydrofluoric acid.

FIG. 8 is a cross-sectional view showing a pixel portion of an active matrix substrate in Embodiment 2.

FIG. 9A is a cross-sectional view showing a step in a process for producing the active matrix substrate shown in FIG. 8, the step being a step of forming a metal film that will become a bias line.

FIG. 9B is a cross-sectional view showing a step of patterning the metal film shown in FIG. 9A so as to form the bias line.

FIG. 9C is a cross-sectional view showing a step of cleaning the surface of the p-type amorphous semiconductor layer shown in FIG. 9B with use of hydrofluoric acid.

FIG. 9D is a cross-sectional view showing a step of forming a transparent conductive film that will become the upper electrode shown in FIG. 8.

FIG. 9E is a cross-sectional view showing a step of patterning the transparent conductive film shown in FIG. 9D so as to form the upper electrode.

FIG. 10 is an enlarged cross-sectional view showing a part of the active matrix substrate shown in FIG. 8, explaining the thicknesses of the p-type amorphous semiconductor layer and the third insulating film.

FIG. 11A is a cross-sectional view showing a step in a process in Embodiment 3 for producing an active matrix substrate, the step being a step of cleaning a surface of a p-type amorphous semiconductor layer with use of hydrofluoric acid.

FIG. 11B is a cross-sectional view showing a step of forming a metal film that will become the bias line shown in FIG. 8.

FIG. 11C is a cross-sectional view showing a step of patterning the metal film shown in FIG. 11B so as to form the bias line, and cleaning the surface of the p-type amorphous semiconductor layer with use of hydrofluoric acid.

FIG. 12A is an enlarged cross-sectional view showing the p-type amorphous semiconductor layer and the third insulating film after the first round of the treatment with use of hydrofluoric acid (the step shown in FIG. 6J).

FIG. 12B is an enlarged cross-sectional view showing the p-type amorphous semiconductor layer and the third insulating film after the second round of the treatment with use of hydrofluoric acid (the step shown in FIG. 11A).

FIG. 12C is an enlarged cross-sectional view showing the p-type amorphous semiconductor layer and the third insulating film after the third round of the treatment with use of hydrofluoric acid (the step shown in FIG. 11C).

FIG. 13A is a cross-sectional view showing a process for producing an active matrix substrate in Modification Example (1), the step being a step of forming a fourth insulating film after the step shown in FIG. 6L

FIG. 13B is a cross-sectional view showing a step of forming an opening of the fourth insulating film shown in FIG. 13A.

FIG. 13C is a cross-sectional view showing a step of forming an opening of the third insulating film shown in FIG. 13B.

FIG. 13D illustrates a step of cleaning the surface of the p-type amorphous semiconductor layer shown in FIG. 13C with use of hydrofluoric acid.

FIG. 14A is a cross-sectional view showing a process for producing an active matrix substrate in Modification Example (2), the step being a step of forming a fourth insulating film after the step shown in FIG. 6L

FIG. 14B is a cross-sectional view showing a step of forming an opening of the fourth insulating film shown in FIG. 14A.

FIG. 14C is a cross-sectional view showing a step of forming an opening in the third insulating film shown in FIG. 14B.

FIG. 14D is a cross-sectional view showing a step of forming a metal film that will become the bias line shown in FIG. 8.

FIG. 14E is a cross-sectional view showing a step of patterning the metal film shown in FIG. 14D so as to form the bias line, and cleaning the surface of the p-type amorphous semiconductor layer with use of hydrofluoric acid.

FIG. 15A is a cross-sectional view showing a process for producing an active matrix substrate in Modification Example (3), the step being a step of forming a metal film that will become the bias line, after the step shown in FIG. 14B.

FIG. 15B is a cross-sectional view showing a step of patterning the metal film shown in FIG. 15A so as to form the bias line.

FIG. 15C is a cross-sectional view showing a step of forming an opening of the third insulating film shown in FIG. 15B.

FIG. 15D is a cross-sectional view showing a step of cleaning the surface of the p-type amorphous semiconductor layer shown in FIG. 150 with use of hydrofluoric acid.

FIG. 16A is a cross-sectional view showing a process for producing an active matrix substrate in Modification Example (4), the step being a step of forming a metal film that will become the bias line, after the step shown in FIG. 14A.

FIG. 16B is a cross-sectional view showing a step of patterning the metal film shown in FIG. 16A so as to form the bias line.

FIG. 16C is a cross-sectional view showing a step of forming an opening of the fourth insulating film shown in FIG. 16B.

FIG. 16D is a cross-sectional view showing a step of forming an opening of the third insulating film shown in FIG. 16C.

FIG. 16E is a cross-sectional view showing a step of cleaning the surface of the p-type amorphous semiconductor layer shown in FIG. 16D with use of hydrofluoric acid.

FIG. 17 is an enlarged cross-sectional view showing a part of an active matrix substrate in Modification Example (5), for explaining the thicknesses of the p-type amorphous semiconductor layer and the third insulating film.

### MODE FOR CARRYING OUT THE INVENTION

An active matrix substrate according to an embodiment of the present invention is an active matrix substrate having a plurality of detection circuitry are arranged in matrix. Each of the detection circuitry includes: a photoelectric conversion layer; a first electrode provided on a first surface of the photoelectric conversion layer; a second electrode provided on a second surface of the photoelectric conversion layer, the second surface being on a side opposite to the side of the first surface; a first insulating film that covers an end portion of the second surface and a side surface of the photoelectric conversion layer, and has a first opening on the second surface; and a second insulating film that overlaps with the first insulating film, and has a second opening that has an opening width greater than that of the first opening, the second opening being on the second surface. The second electrode is in contact with the second surface in the first opening, and is in contact with the first insulating film and the second insulating film (the first configuration).

According to the first configuration, the first electrode is connected to the first surface of the photoelectric conversion layer in the detection circuitry, and the second electrode is connected to the second surface thereof. The end portion of the second surface and the side surface of the photoelectric conversion layer are covered with the first insulating film, and the first opening is provided on the second surface. The second insulating film is provided on the first insulating film, and the second opening is provided on the second surface. The second opening has an opening width greater than that of the first opening. In other words, the second insulating film does not become overhung with respect to the first insulating film. It is therefore unlikely that the second electrode would have disconnections at step portions of the first insulating film and the second insulating film as compared with a case where the second insulating film is overhung with respect to the first insulating film, which makes it unlikely that contact defects would occur between the second electrode and the photoelectric conversion layer.

The first configuration may be further characterized in that a portion of the photoelectric conversion layer in the first opening has a thickness that is smaller than that of a portion of the photoelectric conversion layer on which the first insulating film overlaps (the second configuration).

According to the second configuration, the portion of the photoelectric conversion layer in the first opening has a thickness smaller than that of the portion of the photoelectric conversion layer with which the first insulating film overlaps. For example, in a case where the surface of the photoelectric conversion layer is cleaned with use of hydrofluoric acid after the first insulating film and the second insulating film are formed, the surface of the photoelectric conversion layer not covered with the first insulating film is etched with hydrofluoric acid, thereby to have a smaller thickness. Even in this case, in the present configuration, the position of the end portion of the first insulating film on the photoelectric conversion layer is arranged on an inner side of the photoelectric conversion layer with respect to the position of the end portion of the second insulating film. In other words, the second insulating film does not become overhung with respect to the first insulating film. This makes it unlikely that the second electrode would have disconnections at the step portions of the first insulating film and the second insulating film, which makes it unlikely that contact defects would occur between the second electrode and the photoelectric conversion layer.

The first or second configuration may be further characterized in that the photoelectric conversion layer includes a first semiconductor layer having a first conductive type, a second semiconductor layer having a second conductive type that is opposite to the first conductive type, and an intrinsic amorphous semiconductor layer provided between the first semiconductor layer and the second semiconductor layer; the first semiconductor layer is in contact with the first electrode; and the second semiconductor layer is in contact with the second electrode and the first insulating film, wherein a portion of the second semiconductor layer in the first opening has a thickness smaller than that of a portion of the second semiconductor layer with which the first insulating film overlaps (the third configuration).

According to the third configuration, in the second semiconductor layer in contact with the first insulating film, the portion thereof in the first opening has a thickness smaller than that of the portion thereof with which the first insulating film overlaps, and the second electrode is in contact with the second semiconductor layer. In a case where the surface of the photoelectric conversion layer, that is, the surface of the second semiconductor layer is cleaned with use of hydrofluoric acid before the second electrode is formed, the surface of the second semiconductor layer is etched, and the thickness of the portion not covered with the first insulating film decreases. Even in this case, the second insulating film does not become overhung with respect to the first insulating film, which makes it unlikely that the second electrode would have disconnections at the step portions of the first insulating film and the second insulating film, and therefore makes it unlikely that contact defects would occur between the second electrode and the second semiconductor layer.

Any one of the first to third configurations may be further characterized in that a portion on the first opening side of the first insulating film has a thickness smaller than that of a portion of the first insulating film that overlaps with the second insulating film (the fourth configuration).

According to the fourth configuration, for example, in a case where the surface of the photoelectric conversion layer is cleaned with use of hydrofluoric acid after the first opening and the second opening are formed and before the second electrode is formed, a portion of the surface of the first insulating film that is not covered with the second insulating film is etched with hydrofluoric acid in some cases. A portion on the first opening side of the first insulating film has a thickness smaller than that of a portion thereof with which the second insulating film overlaps. Even in this case, the second insulating film does not become overhung with respect to the first insulating film, which makes it unlikely that the second electrode would have disconnections at step portions of the first insulating film and the second insulating film.

An imaging panel according to one embodiment of the present invention includes: the active matrix substrate according to any one of the first to fourth configurations; and a scintillator that convers (the fifth configuration).

According to the fifth configuration, it is unlikely that the second electrode would have disconnections at step portions of the first insulating film and the second insulating film, which makes it unlikely that contact defects would occur between the second electrode and the photoelectric conversion layer. It is therefore possible to decrease X-ray detection defects.

A method for producing an active matrix substrate according to one embodiment of the present invention is a method for producing an active matrix substrate that includes the steps of, in each of areas where the detection circuitry on the substrate are provided, respectively: forming a first electrode; forming a photoelectric conversion layer on the first electrode; forming a first insulating film that covers an end portion of a second surface and a side surface of the photoelectric conversion layer, and has a first opening on the second surface, the second surface being on a side opposite to a first surface of the photoelectric conversion layer which the first electrode is in contact with; forming a second insulating film that overlaps with the first insulating film, and has a second opening on the second surface, the second opening having an opening width greater than that of the first opening; and forming a second electrode that is in contact with the second surface in the first opening, and is in contact with the first insulating film and the second insulating film (the first producing method).

According to the first configuration, the first electrode is connected to the first surface of the photoelectric conversion layer in the detection circuitry, and the second electrode is connected to the second surface thereof. The end portion of the second surface and the side surface of the photoelectric conversion layer are covered with the first insulating film, and the first opening is provided on the second surface. The second insulating film is provided on the first insulating film, and the second opening is provided on the second surface. The second opening has an opening width greater than that of the first opening. In other words, the second insulating film does not become overhung with respect to the first insulating film. It is therefore unlikely that the second electrode would have disconnections at step portions of the first insulating film and the second insulating film when the second electrode is formed, which makes it unlikely that contact defects would occur between the second electrode and the photoelectric conversion layer.

The first producing method may be further characterized in that, in the step of forming the first insulating film, the first insulating film is etched with use of hydrofluoric acid so as to form the first opening, and a portion of the photoelectric conversion layer in the first opening has a thickness smaller than that of a portion of the photoelectric conversion layer with which the first insulating film overlaps (the second producing method).

According to the second producing method, by the etching of the first insulating film with use of hydrofluoric acid, a portion of the photoelectric conversion layer in the first opening has a thickness smaller than that of a portion of the photoelectric conversion layer with which the first insulating film overlaps, but the second insulating film does not become overhung with respect to the first insulating film. As a result, as compared with a case where the second insulating film is overhung with respect to the first insulating film, it is unlikely that the second electrode would have disconnections at steps portion of the first insulating film and the second insulating film when the second electrode is formed, which makes it unlikely that contact defects would occur between the second electrode and the photoelectric conversion layer. Further, since the surface of the photoelectric conversion layer is etched with hydrofluoric acid, organic matters such as native oxides adhering to the surface of the photoelectric conversion layer are also removed, which makes it unlikely that leakage current of the photoelectric conversion layer would flow.

The first or second producing method may be further characterized in further including the step of cleaning the second surface in the first opening with use of hydrofluoric acid, after the first insulating film is formed, before the second electrode is formed (the third producing method).

According to the third producing method, the second surface of the photoelectric conversion layer is cleaned with use of hydrofluoric acid. Organic matters such as native oxides adhering to the surface of the photoelectric conversion layer are therefore removed, which makes it unlikely that leakage current of the photoelectric conversion layer would flow.

Any one of the first to third producing method may be further characterized in further including the step of: forming a bias line that overlaps with the second electrode, on the second insulating film on an outer side with respect to the photoelectric conversion layer; and cleaning the second surface in the first opening with use of hydrofluoric acid, before the second electrode and the bias line are formed (the fourth producing method).

According to the fourth producing method, before the steps of forming the second electrode and the bias line, the second surface of the photoelectric conversion layer is cleaned with use of hydrofluoric acid. Organic matters such as native oxides adhering to the second surface are therefore removed, which makes it unlikely that leakage current of the photoelectric conversion layer would flow.

The following description describes embodiments of the present invention in detail, while referring to the drawings. Identical or equivalent parts in the drawings are denoted by the same reference numerals, and the descriptions of the same are not repeated.

### Embodiment 1

### (Configuration)

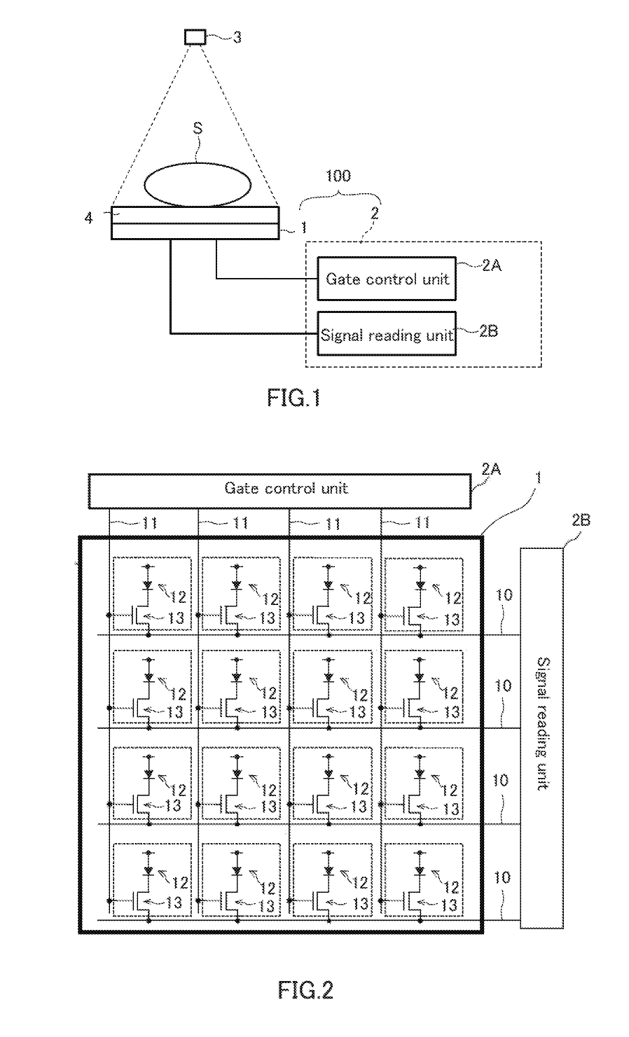

FIG. 1 schematically illustrates an X-ray imaging device in the present embodiment. The X-ray imaging device 100 includes an active matrix substrate 1 and a control unit 2. The control unit 2 includes a gate control unit 2A and a signal reading unit 2B. X-rays are projected from the X-ray source 3 to an object S, and X-rays transmitted through the object S are converted into fluorescence (hereinafter referred to as scintillation light) by a scintillator 4 provided above the active matrix substrate 1. The X-ray imaging device 100 picks up the scintillation light with the active matrix substrate 1 and the control unit 2, thereby acquiring an X-ray image.

FIG. 2 is a schematic diagram showing a schematic configuration of the active matrix substrate 1. As shown in FIG. 2, a plurality of source lines 10, and a plurality of gate lines 11 intersecting with the source lines 10 are formed in the active matrix substrate 1. The gate lines 11 are connected with the gate control unit 2A, and the source lines 10 are connected with the signal reading unit 2B.

The active matrix substrate 1 includes TFTs 13 connected to the source lines 10 and the gate lines 11, at positions at which the source lines 10 and the gate lines 11 intersect. Further, photodiodes 12 are provided in areas surrounded by the source lines 10 and the gate lines 11 (hereinafter referred to as pixels). In each pixel, scintillation light obtained by converting X-rays transmitted through the object S is converted by the photodiode 12 into charges according to the amount of the light. In other words, the pixels function as detection circuitry that detect scintillation light.

The gate lines 11 in the active matrix substrate 1 are sequentially switched by the gate control unit 2A (see FIGS. 1, 2 and the like) into a selected state, and the TFT 13 connected to the gate line 11 in the selected state is turned ON. When the TFT 13 is turned ON, a signal according to the charges obtained by the conversion by the photodiode 12 is output through the source line 10 to the signal reading unit 2B (see FIGS. 1, 2 and the like).

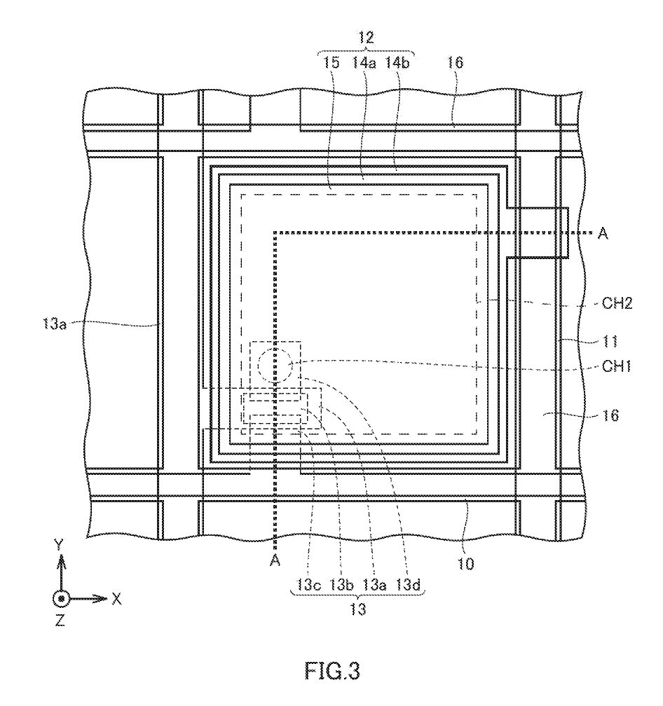

FIG. 3 is an enlarged plan view of one pixel portion of the active matrix substrate 1 shown in FIG. 2. As shown in FIG. 3, in the pixel surrounded by the gate lines 11 and the source lines 10, the photodiode 12 and the TFT 13 are arranged.

The photodiode 12 includes a lower electrode 14a and an upper electrode 14b as a pair of a first electrode and a second electrode, and a photoelectric conversion layer 15.

The upper electrode 14b is provided on the photoelectric conversion layer 15, that is, on a side that is irradiated with X-rays from the X-ray source 3 (see FIG. 1).

The TFT 13 includes a gate electrode 13a integrated with the gate line 11, a semiconductor active layer 13b, a source electrode 13c integrated with the source line 10, and a drain electrode 13d.

Further, the bias line 16 is arranged so as to overlap with the gate line 11 and the source line 10 when viewed in a plan view. The bias line 16 supplies a bias voltage to the photodiode 12.

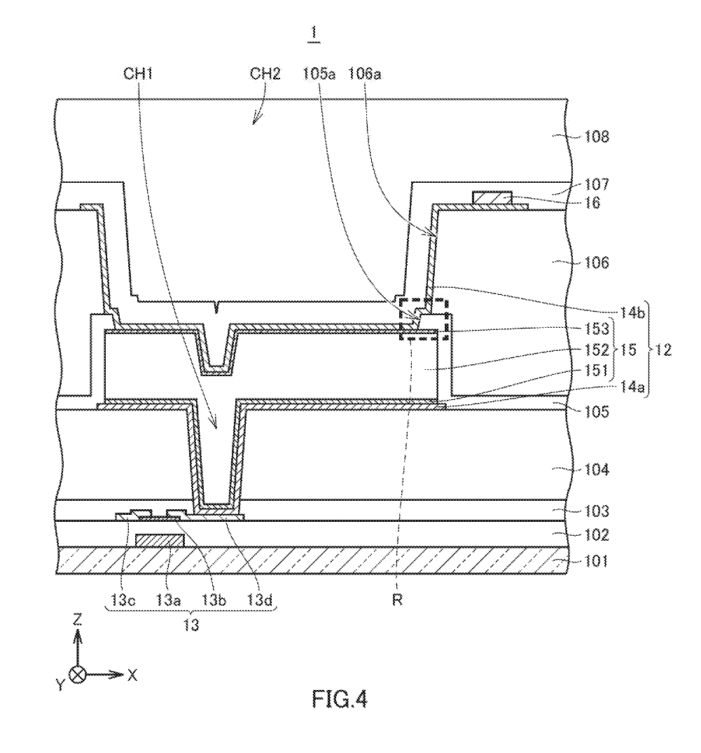

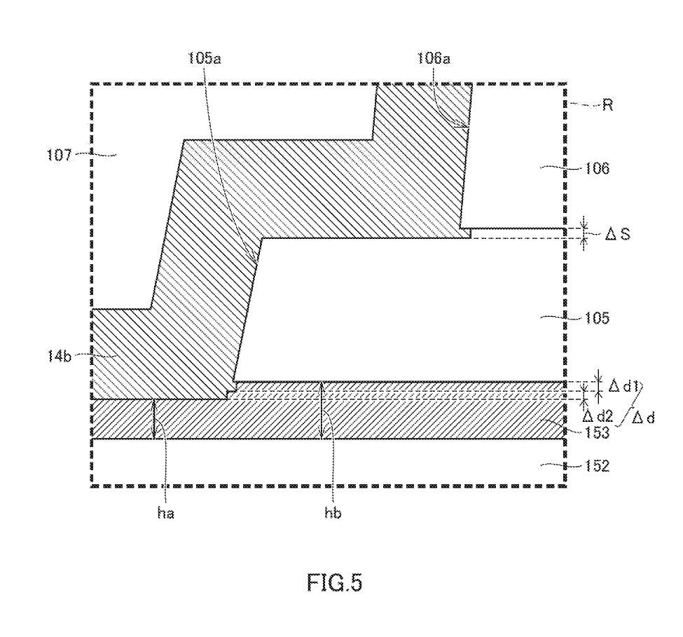

Here, FIG. 4 illustrates a cross-sectional view of the pixel shown in FIG. 3 taken along line A-A. As shown in FIG. 4, each element in the pixel is arranged on the substrate 101. The substrate 101 is a substrate having insulating properties, and is formed with, for example, a glass substrate.

On the substrate 101, the gate electrode 13a integrated with the gate line 11 (see FIG. 3), and a gate insulating film 102.

The gate electrode 13a and the gate line 11 are made of, for example, a metal such as aluminum (Al), tungsten (W), molybdenum (Mo), molybdenum nitride (MoN), tantalum (Ta), chromium (Cr), titanium (Ti), or copper (Cu), an alloy of any of these metals, or a metal nitride of these metals. In this example, the gate electrode 13a and the gate line 11 may have laminate structures each of which is obtained by laminating a metal film made of molybdenum nitride (MoN) as an upper layer, and a metal film made of aluminum (Al) as a lower layer. In this case, the metal film made of molybdenum nitride (MoN) preferably has a thickness of about 100 nm, and the metal film made of aluminum (Al) preferably has a thickness of about 300 nm. The materials and the thicknesses of the gate electrode 13a and the gate line 11, however, are not muted to these.

The gate insulating film 102 covers the gate electrode 13a. For forming the gate insulating film 102, for example, the following can be used: silicon oxide (SiOₓ); silicon nitride (SiNₓ); silicon oxide nitride (SiOₓN_{y})(x>y); or silicon nitride oxide (SiNₓO_{y})(x>y).

In this example, the gate insulating film 102 may be formed with a laminate film obtained by laminating silicon oxide (SiOₓ) and silicon nitride (SiNₓ) in the order. In this case, regarding the thicknesses of these films, it is preferable that the film of silicon oxide (SiOₓ) has a thickness of about 50 nm, and the film of silicon nitride (SiNₓ) has a thickness of about 400 nm. The material and the thickness of the gate insulating film 102, however, are not limited to these.

The semiconductor active layer 13b, as well as the source electrode 13c and the drain electrode 13d connected with the semiconductor active layer 13b are formed on the gate electrode 13a with the gate insulating film 102 being interposed therebetween.

The semiconductor active layer 13b is formed in contact with the gate insulating film 102. The semiconductor active layer 13b is made of an oxide semiconductor. For forming the oxide semiconductor, for example, the following material may be used: InGaO₃(ZnO)₅; magnesium zinc oxide (MgₓZn₁₋ₓO); cadmium zinc oxide (CdₓZn₁₋ₓO); cadmium oxide (CdO); or an amorphous oxide semiconductor containing indium (In), gallium (Ga), and zinc (Zn) at a predetermined ratio.

In this example, it is preferable that the semiconductor active layer 13b is made of, for example, an amorphous oxide semiconductor containing indium (In), gallium (Ga), and zinc (Zn) at a predetermined ratio, and has a thickness of about 70 nm. The material and the thickness of the semiconductor active layer 13b, however, are not limited to these.

The source electrode 13c and the drain electrode 13d, on the gate insulating film 102, are arranged so as to be in contact with parts of the semiconductor active layer 13b. The drain electrode 13d is connected with the lower electrode 14a through the contact hole CH1.

The source electrode 13c and the drain electrode 13d are formed in the same layer, and are made of, for example, a metal such as aluminum (Al), tungsten (W), molybdenum (Mo), tantalum (Ta), chromium (Cr), titanium (Ti), or copper (Cu), or alternatively, an alloy of any of these, of a metal nitride of any of these. Further, as the material for the source electrode 13c and the drain electrode 13d, the following material may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or a material obtained by appropriately combining any of these.

In this example, the source electrode 13c and the drain electrode 13d has a laminate structure obtained by laminating a plurality of metal films. More specifically, the source electrode 13c and the drain electrode 13d are formed with a metal film made of molybdenum nitride (MoN), a metal film made of aluminum (Al), and a metal film made of molybdenum nitride (MoN) which are laminated in this order. In this case, regarding the thicknesses of the films, preferably, the metal film in the lower layer, which is made of molybdenum nitride (MoN), has a thickness of about 50 nm, the metal film made of aluminum (Al) has a thickness of about 500 nm, and the metal film in the upper layer, which is made of molybdenum nitride (MoN), has a thickness of about 100 nm. The materials and the thicknesses of the source electrode 13c and the drain electrode 13d, however, are not limited to these.

A first insulating film 103 is provided so as to cover the source electrode 13c and the drain electrode 13d. In this example, the first insulating film 103 has a laminate structure obtained by laminating silicon nitride (SiN) and silicon oxide (SiO₂) in this order. In this case, it is preferable that, for example, the silicon nitride (SiN) film has a thickness of about 330 nm, and the silicon oxide (SiO₂) film has a thickness of about 200 nm. The material and the thickness of the first insulating film 103, however, are not limited to these. Further, the first insulating film 103 may have a single layer structure made of silicon oxide (SiO₂) or silicon nitride (SiN).

On the first insulating film 103, a second insulating film 104 is formed. On the drain electrode 13d, the contact hole CH1 is formed. The contact hole CH1 passes through the second insulating film 104 and the first insulating film 103. In this example, the second insulating film 104 is formed with an organic transparent resin such as acrylic resin or siloxane-based resin. In this case, the second insulating film 104 preferably has a thickness of about 2.5 μm. The thickness of the second insulating film 104, however, is not limited to this.

On the second insulating film 104, the lower electrode 14a is formed. The lower electrode 14a is connected with the drain electrode 13d through the contact hole CH1. In this example, the lower electrode 14a is formed with, for example, a metal film containing molybdenum nitride (MoN). In this case, the lower electrode 14a preferably has a thickness of about 200 nm. The material and the thickness of the lower electrode 14a, however, are not limited to these.

On the lower electrode 14a, the photoelectric conversion layer 15 is formed. The photoelectric conversion layer 15 is composed of the n-type amorphous semiconductor layer 151, the intrinsic amorphous semiconductor layer 152, and the p-type amorphous semiconductor layer 153, which are laminated in the order. In this example, the photoelectric conversion layer 15 has an X-axis-direction length shorter than the X-axis-direction length of the lower electrode 14a.

The n-type amorphous semiconductor layer 151 is made of amorphous silicon doped with an n-type impurity (for example, phosphorus). In this example, the n-type amorphous semiconductor layer 151 preferably has a thickness of about 30 nm. The dopant material and the thickness of the n-type amorphous semiconductor layer 151, however, are not limited to these.

The intrinsic amorphous semiconductor layer 152 is made of intrinsic amorphous silicon. The intrinsic amorphous semiconductor layer 152 is formed in contact with the n-type amorphous semiconductor layer 151. In this example, the intrinsic amorphous semiconductor layer preferably has a thickness of about 1000 nm, but the thickness thereof is not limited to this.

The p-type amorphous semiconductor layer 153 is made of amorphous silicon doped with a p-type impurity (for example, boron). The p-type amorphous semiconductor layer 153 is formed in contact with the intrinsic amorphous semiconductor layer 152. In this example, the p-type amorphous semiconductor layer 153 preferably has a thickness of about 5 nm. The dopant material and the thickness of the p-type amorphous semiconductor layer 153, however, are not limited to these.

On the second insulating film 104, the third insulating film 105 is provided. The third insulating film 105 covers the end portions of the top surface and the side surfaces of the lower electrode 14a and the photoelectric conversion layer 15, and has an opening 105a on the photoelectric conversion layer 15. In this example, the third insulating film 105 is an inorganic insulating film made of, for example, silicon nitride (SiN). The third insulating film 105 preferably has a thickness of about 300 nm. The material and the thickness of the third insulating film 105 are not limited to these.

On the third insulating film 105, the fourth insulating film 106 is provided. The fourth insulating film 106 has an opening 106a on the opening 105a of the third insulating film 105, the opening 106a having a greater opening width than the width of the opening 105a. The fourth insulating film 106 is provided so as to overlap with the side surfaces of the photoelectric conversion layer 15 when viewed in a plan view. In other words, the fourth insulating film 106 covers the side surfaces of the photoelectric conversion layer 15 with the third insulating film 105 being interposed between the fourth insulating film 106 and the photoelectric conversion layer 15. The openings 105a and 106a compose a contact hole CH2. In this example, the fourth insulating film 106 is an organic insulating film made of, for example, acrylic resin or siloxane-based resin. The fourth insulating film 106 preferably has a thickness of about 2.5 μm. The material and the thickness of the fourth insulating film 106, however, are not limited to these.

Here, FIG. 5 shows an enlarged view of the broken-line frame R part in FIG. 4. As shown in FIG. 5, the openings 105a and 106a of the third insulating film 105 and the fourth insulating film 106 are provided in such a manner that the position of an end portion of the third insulating film 105 on the p-type amorphous semiconductor layer 153 is on an inner side of the p-type amorphous semiconductor layer 153 with respect to the position of an end portion of the fourth insulating film 106, that is, on an inner side in the in-plane direction of the surface of the p-type amorphous semiconductor layer 153. In the p-type amorphous semiconductor layer 153, a non-opening portion overlapping with the third insulating film 105 has a thickness hb. The thickness of a portion under the opening 105a and which the third insulating film 105 does not overlap in the p-type amorphous semiconductor layer 153 has a smaller thickness ha by Δd (Δd1+Δd2) than the thickness hb (ha<hb). In other words, in the p-type amorphous semiconductor layer 153, the portion thereof under the opening 105a of the third insulating film 105 and the non-opening portion thereof have different thicknesses, respectively. Further, in the present embodiment, in the third insulating film 105, an end portion thereof on the opening 105a side has a thickness that is Δs (for example, about 5 nm) smaller than the thickness of the other portion so that the end portion is positioned at Δs from the lower surface of the fourth insulating film 106. This is caused by the treatment with use of hydrofluoric acid in the process of producing the active matrix substrate 1. This is specifically described below in the description of the method for producing the active matrix substrate 1.

Referring back to FIG. 4, the upper electrode 14b is in contact with the photoelectric conversion layer 15 in the contact hole CH2. The upper electrode 14b is formed with a transparent conductive film, and in this example, it is made of indium tin oxide (ITO). The upper electrode 14b preferably has a thickness of about 70 nm. The material and the thickness of the upper electrode 14b, however, are not limited to these.

The bias line 16 is provided on the upper electrode 14b on an outer side with respect to the photoelectric conversion layer 15. The bias line 16 is connected to the control unit 2 (see FIG. 1), and applies a bias voltage input from the control unit 2 to the upper electrode 14b. The bias line 16 is formed with a single-layer metal film or a multiple-layer metal film.

In this example, the bias line 16 has a laminate structure obtained by laminating a metal film made of molybdenum nitride (MoN), a metal film made of aluminum (Al), and a metal film made of molybdenum nitride (MoN). In this case, the molybdenum nitride (MoN) film in the lower layer has a thickness of about 50 nm, the aluminum (Al) film preferably has a thickness of about 300 nm, and the molybdenum nitride (MoN) film in the upper layer has a thickness of about 100 nm. The material and the thickness of the bias line 16, however, are not limited to these.

A fifth insulating film 107 is provided so as to cover the bias line 16 and the fourth insulating film 106. The fifth insulating film 107 is an inorganic insulating film, and in this example, it is made of silicon nitride (SiN). In this case, the fifth insulating film 107 preferably has a thickness of about 200 nm. The material and the thickness of the fifth insulating film 107, however, are not limited to these.

A sixth insulating film 108 is provided so as to cover the fifth insulating film 107. The sixth insulating film 108 is an organic insulating film, and in this example, it is made of an organic transparent resin such as acrylic resin or siloxane-based resin.

The sixth insulating film 108 preferably has a thickness of about 2.0 lam. The material and the thickness of the sixth insulating film 108, however, are not limited to these.

### (Method for Producing Active Matrix Substrate 1)

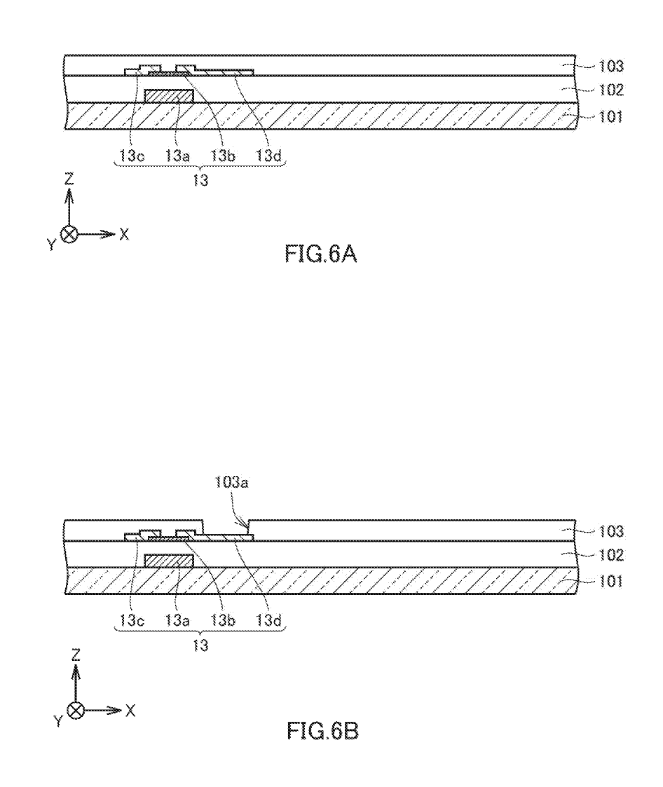

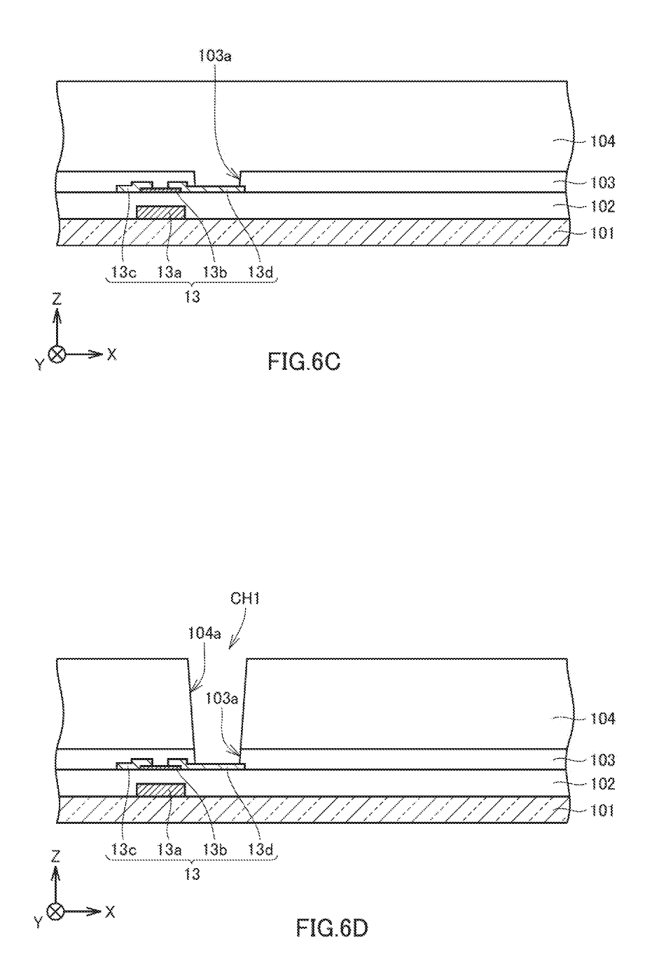

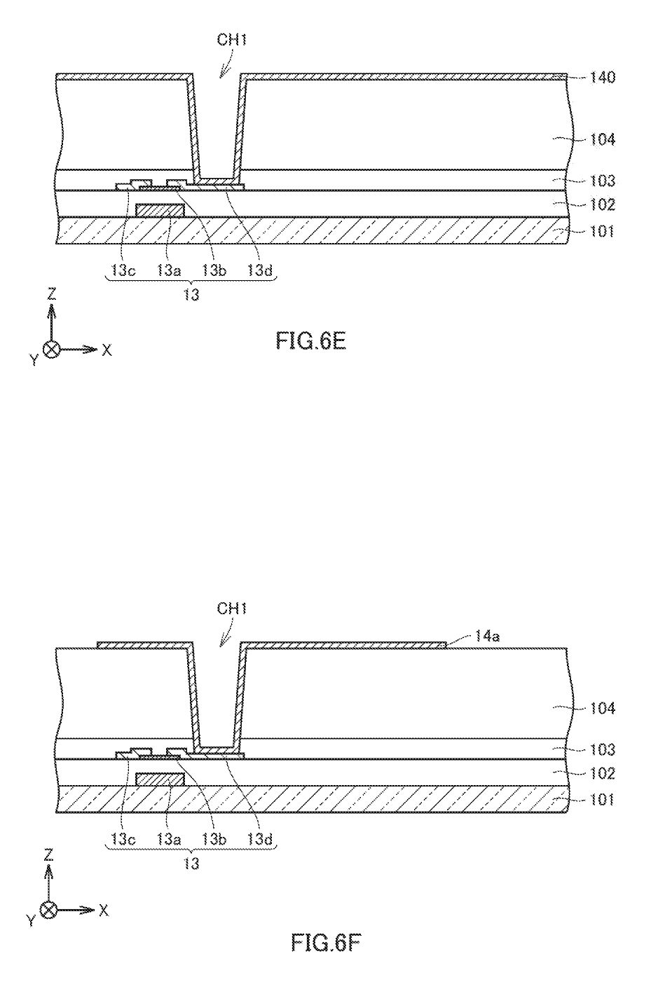

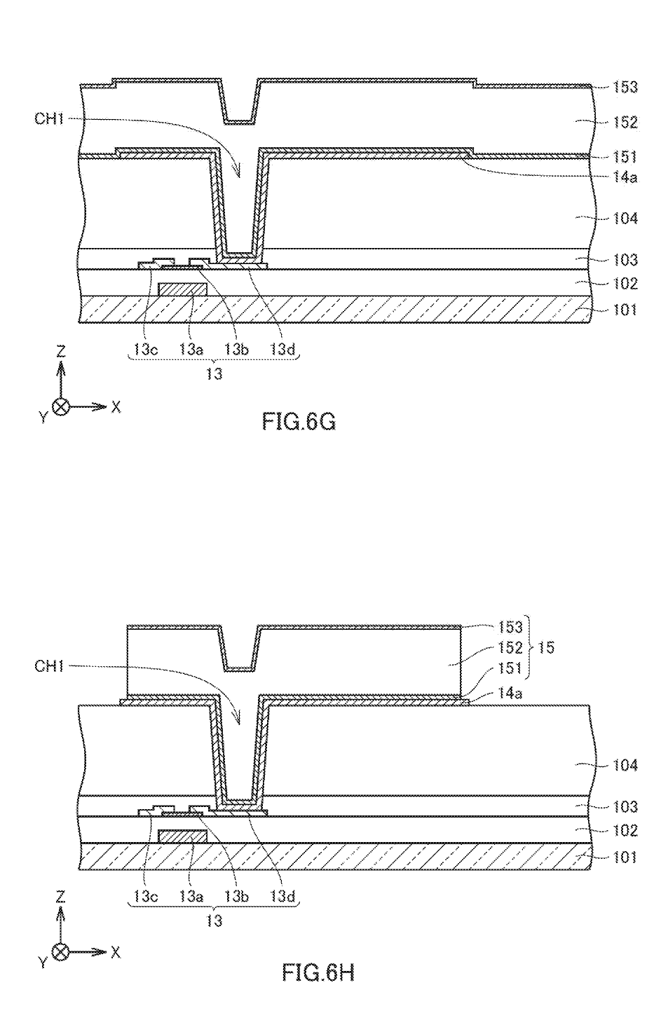

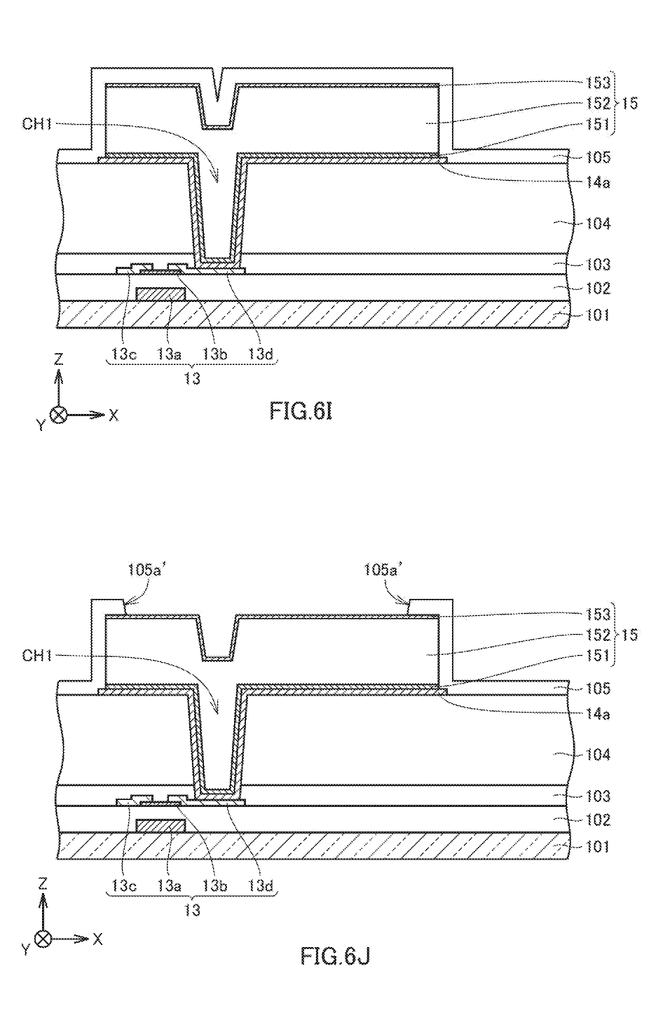

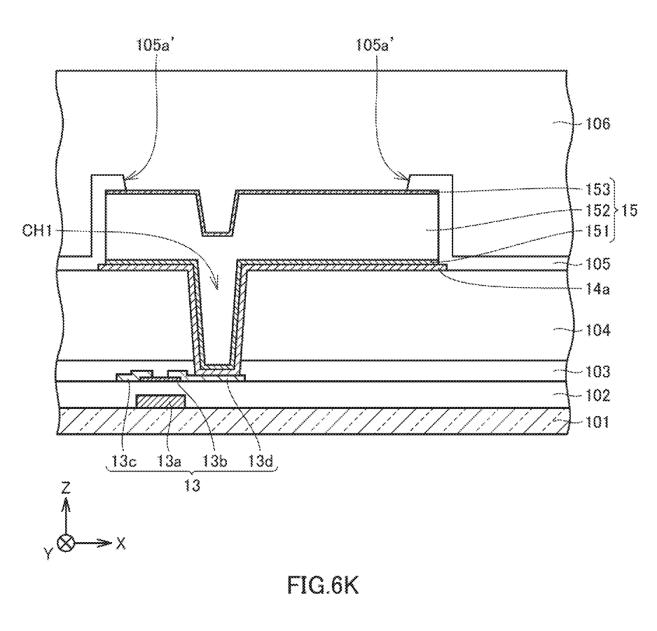

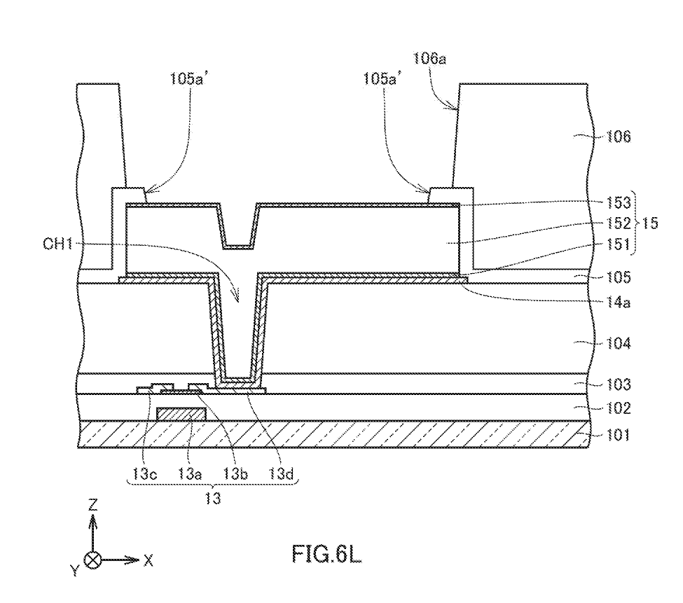

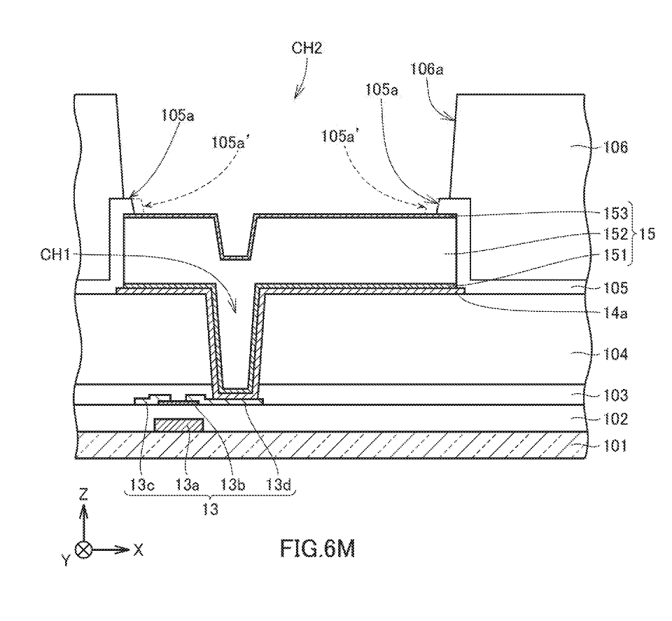

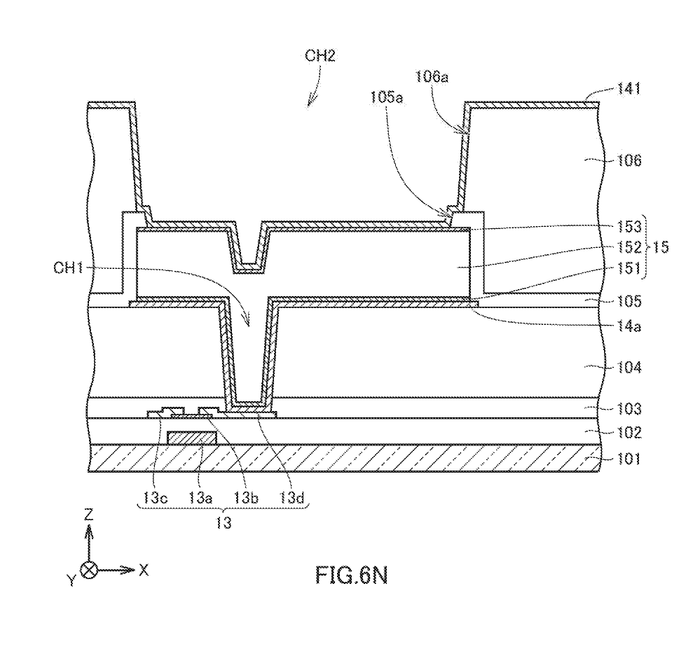

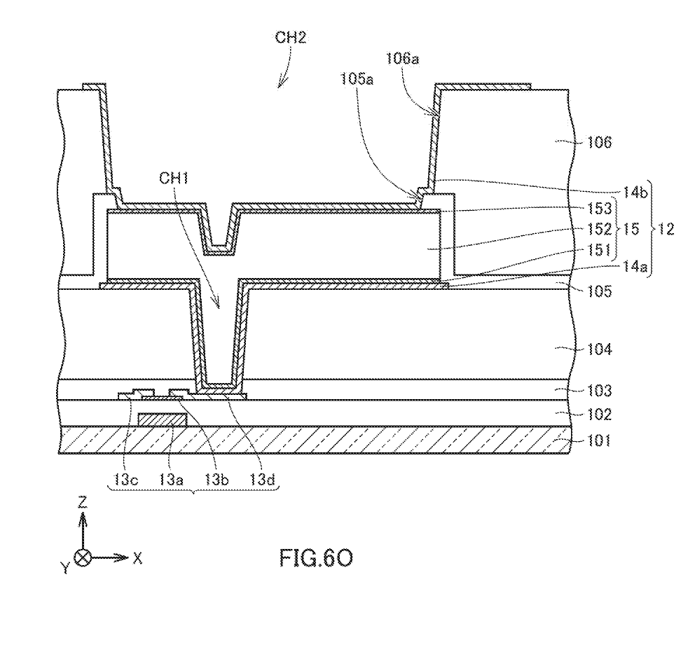

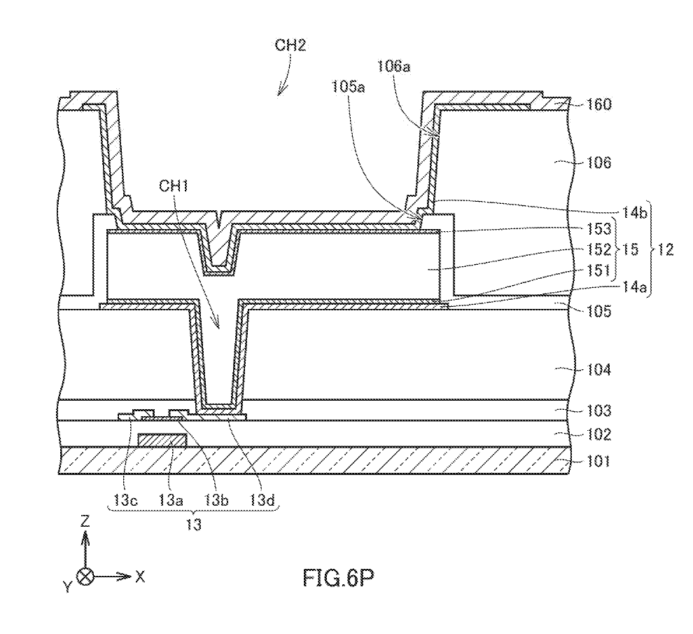

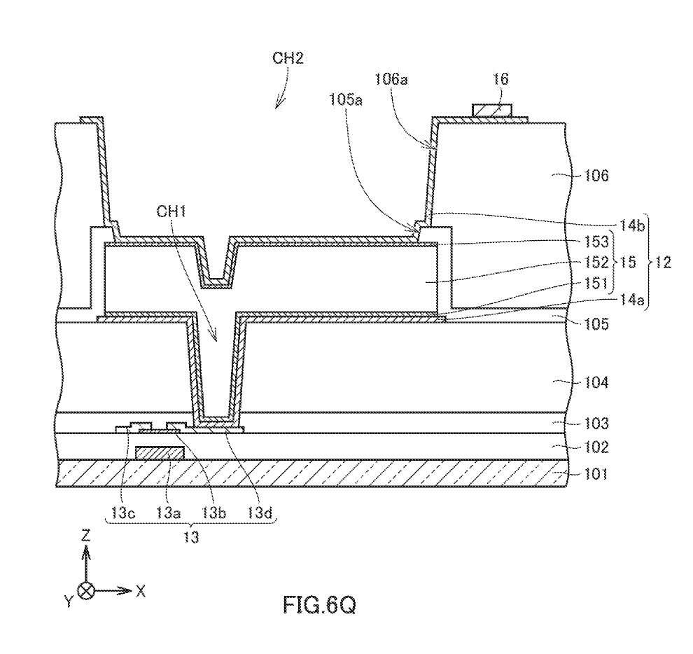

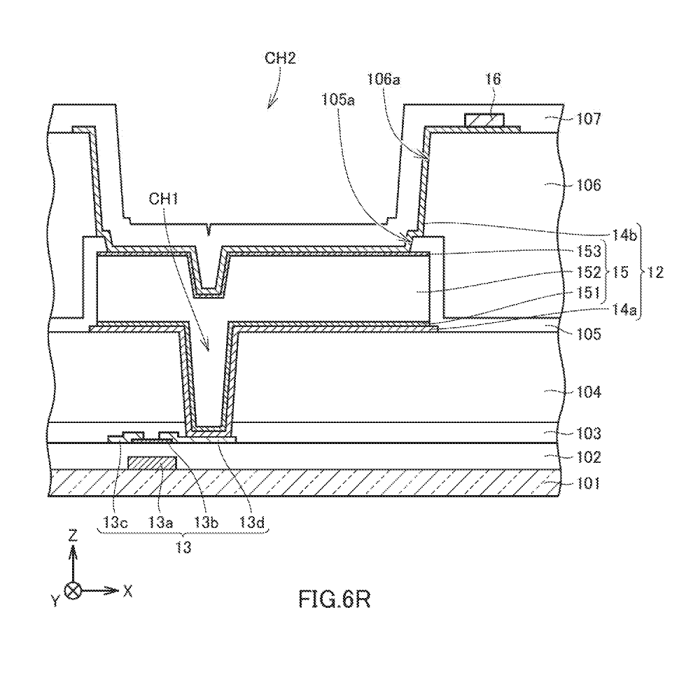

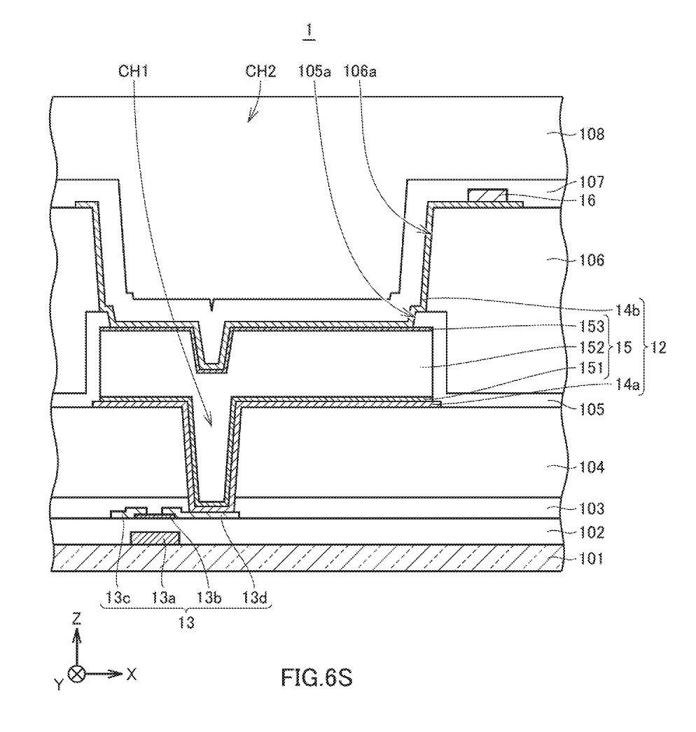

Next, the following description describes a method for producing the active matrix substrate 1. FIGS. 6A to 6S are cross-sectional views (taken along line A-A in FIG. 3) in respective steps of the method for producing the active matrix substrate 1.

As shown in FIG. 6A, the gate insulating film 102 and the TFT 13 are formed on the substrate 101 by using a known method, and the first insulating film 103 is formed by laminating silicon oxide (SiO2) and silicon nitride (SiN), so as to cover the TFT 13 by using, for example, plasma CVD.

Subsequently, a heat treatment at about 350° C. is applied to an entire surface of the substrate 101, and photolithography and wet etching are carried out so as to pattern the first insulating film 103, whereby the opening 103a is formed on the drain electrode 13d (see FIG. 6B).

Next, the second insulating film 104 made of acrylic resin or siloxane-based resin is formed on the first insulating film 103 by using, for example, slit-coating (see FIG. 6C).

Then, the opening 104a in the second insulating film 104 is formed on the opening 103a by using photolithography. Through these steps, the contact hole CH1 composed of the openings 103a and 104a is formed (see FIG. 6D).

Subsequently, the metal film 140 made of molybdenum nitride (MoN) is formed on the second insulating film 104 by using, for example, sputtering (see FIG. 6E).

Then, photolithography and wet etching are carried out so as to pattern the metal film 140. As a result, the lower electrode 14a connected through the contact hole CH1 with the drain electrode 13d is formed on the second insulating film 104 (see FIG. 6F).

Next, the n-type amorphous semiconductor layer 151, the intrinsic amorphous semiconductor layer 152, and the p-type amorphous semiconductor layer 153 are formed in this order so as to cover the second insulating film 104 and the lower electrode 14a by using, for example, plasma CVD (see FIG. 6G).

Then, photolithography and dry etching are carried out, whereby the n-type amorphous semiconductor layer 151, the intrinsic amorphous semiconductor layer 152, and the p-type amorphous semiconductor layer 153 are patterned. As a result, the photoelectric conversion layer 15 is formed (see FIG. 6H).

Next, the third insulating film 105 made of silicon nitride (SiN) is formed so as to cover the surface of the photoelectric conversion layer 15, by using, for example, plasma CVD (see FIG. 6I).

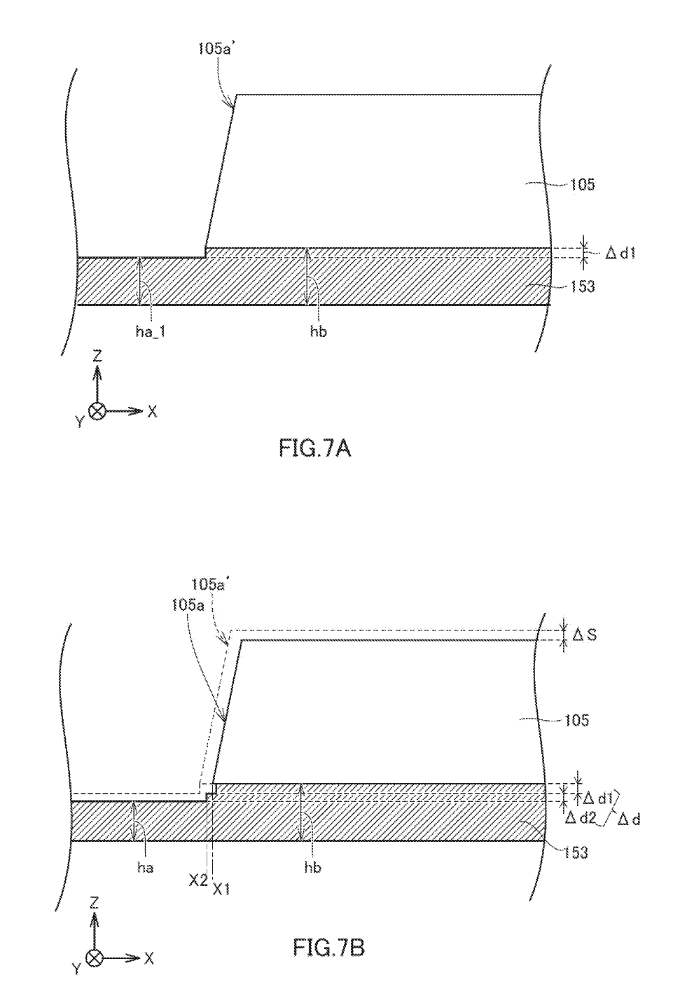

Then, photolithography and wet etching are carried out so as to pattern the third insulating film 105, whereby the opening 105a′ of the third insulating film 105 is formed on the photoelectric conversion layer 15 (see FIG. 6J). For this wet etching, for example, an etchant containing hydrofluoric acid may be used. FIG. 7A is an enlarged cross-sectional view showing the third insulating film 105 and the p-type amorphous semiconductor layer 153 after the step shown in FIG. 6J. In this example, anisotropic etching is carried out to the third insulating film 105. In this case, not only an opening 105a′ is formed in the third insulating film 105 by etching, but also the surface of the p-type amorphous semiconductor layer 153 is etched, whereby the p-type amorphous semiconductor layer 153 has a thickness decreased by Δd1.

Here, anisotropic etching is carried out to the third insulating film 105, but isotropic etching may be carried out instead. In the case of isotropic etching, the width in which the third insulating film 105 is side-etching is greater than that in the case of anisotropic etching.

Subsequently, the fourth insulating film 106 made of acrylic resin or siloxane-based resin is formed on the third insulating film 105 by using, for example, slit-coating (see FIG. 6K). Thereafter, photolithography and wet etching are carried out so as to form an opening 106a in the fourth insulating film 106, the opening 106a having an opening width greater than that of the opening 105a′ of the third insulating film 105 (see FIG. 6L). Through these steps, the contact hole CH2 composed of the openings 105a′ and 106a is formed.

Thereafter, a native oxide film adhering to the surface of the p-type amorphous semiconductor layer 153 is removed with use of hydrofluoric acid. Through these steps, an end portion of the third insulating film 105 is etched by hydrofluoric acid, whereby the opening 105a, which is greater than the opening 105a′, is formed (see FIG. 6M). As shown in FIG. 6M, even if the end portion of the third insulating film 105 is etched by hydrofluoric acid, the opening 105a of the third insulating film 105 has an opening width smaller than the opening width of the opening 106a of the fourth insulating film 106. In other words, the position of the end portion of the third insulating film 105 is arranged at a position on an inner side in the in-plane direction of the photoelectric conversion layer 15 with respect to the end portion of the fourth insulating film 106.

Further, in this cleaning treatment with use of hydrofluoric acid, the surfaces of the p-type amorphous semiconductor layer 153 and the third insulating film 105 are eroded, while the native oxide film on the surface of the p-type amorphous semiconductor layer 153 is removed. FIG. 7B is an enlarged cross-sectional view showing a part of the p-type amorphous semiconductor layer 153 and the third insulating film 105 after the step shown in FIG. 6M. As shown in FIG. 7B, the third insulating film 105 has a thickness decreased by Δs due to the cleaning treatment, and the end portion of the third insulating film 105 is side-etched. Further, the thickness of the p-type amorphous semiconductor layer 153 under the opening 105a is further decreased by Δd2 by this cleaning treatment, whereby the p-type amorphous semiconductor layer 153 has a step portion thus formed.

In this example, the etching conditions are set so that the rate of etching by hydrofluoric acid with respect to the third insulating film 105 is greater than that with respect to the p-type amorphous semiconductor layer 153. For this reason, the position X1 of the end portion of the third insulating film 105 after the cleaning treatment is arranged on an outer side of the photoelectric conversion layer 15 with respect to the position X2 of the step portion of the p-type amorphous semiconductor layer 153. The etching conditions, however, may be set so that the etching rate with respect to the third insulating film 105 is greater. In this case, in the etching or the cleaning treatment with use of hydrofluoric acid, the p-type amorphous semiconductor layer 153 under the third insulating film 105 is etched toward the inner side of the third insulating film 105, whereby the third insulating film 105 becomes overhung with respect to the p-type amorphous semiconductor layer 153.

After the step shown in FIG. 6M, the transparent conductive film 141 made of ITO is formed on the fourth insulating film 106 by using, for example, sputtering (see FIG. 6N). Subsequently, photolithography and dry etching are carried out so as to pattern the transparent conductive film 141. Through these steps, the upper electrode 14b in contact with the p-type amorphous semiconductor layer 153 of the photoelectric conversion layer 15 is formed (see FIG. 6O).

As shown in FIG. 6M, before the transparent conductive film 141 is formed, the end portion of the third insulating film 105 is arranged on an inner side of the photoelectric conversion layer 15 with respect to the end portion of the fourth insulating film 106, or in other words, the end portion of the third insulating film 105 is arranged on an inner side in the in-plane direction of the photoelectric conversion layer 15, and therefore, the fourth insulating film 106 is not overhung with respect to the third insulating film 105. When the transparent conductive film 141 is formed, the step portions of the third insulating film 105 and the fourth insulating film 106 can be therefore covered with the transparent conductive film 141, whereby it is unlikely that the upper electrode 14b would have disconnections.

Subsequently, a metal film 160 is formed by laminating molybdenum nitride (MoN), aluminum (Al), and molybdenum nitride (MoN) sequentially in this order by using, for example, sputtering so as to cover the upper electrode 14b (see FIG. 6P).

Then, photolithography and wet etching are carried out so as to pattern the metal film 160. Through these steps, on an outer side with respect to the photoelectric conversion layer 15, the bias line 16 is formed on the upper electrode 14b (see FIG. 6Q).

Next, the fifth insulating film 107 made of silicon nitride (SiN) is formed by using, for example, plasma CVD so as to cover the upper electrode 14b and the bias line 16 (see FIG. 6R).

Subsequently, the sixth insulating film 108 made of acrylic resin or siloxane-based resin is formed on the fifth insulating film 107 by using, for example, slit-coating (see FIG. 6 S).

The method described above is the method for producing the active matrix substrate 1 in the present embodiment. As described above, in the present embodiment, the openings 105a, 106a of the third insulating film 105 and the fourth insulating film 106 are formed so that the position of the end portion of the third insulating film 105 is arranged on an inner side in the in-plane direction of the photoelectric conversion layer 15 with respect to the end portion of the fourth insulating film 106. In other words, the fourth insulating film 106 does not become overhung with respect to the third insulating film 105. Further, before the upper electrode 14b is formed, the surface of the p-type amorphous semiconductor layer 153 is cleaned with use of hydrofluoric acid. This allows the upper electrode 14b to hardly have disconnections as compared with a case where the fourth insulating film 106 is overhung with respect to the third insulating film 105. This makes it possible to stabilize the contact resistance between the p-type amorphous semiconductor layer 153 and the upper electrode 14b.

### (Operation of X-Ray Imaging Device 100)

Here, operations of the X-ray imaging device 100 shown in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 are transmitted through an object S, and are incident on the scintillator 4. The X-rays incident on the scintillator 4 are converted into fluorescence (scintillation light), and the scintillation light is incident on the active matrix substrate 1. When the scintillation light is incident on the photodiode 12 provided in each pixel in the active matrix substrate 1, the scintillation light is changed to charges by the photodiode 12 in accordance with the amount of the scintillation light. A signal according to the charges obtained by conversion by the photodiode 12 is read out through the source line 10 to the signal reading unit 2B (see FIG. 2 and the like) when the TFT 13 (see FIG. 3 and the like) is in the ON state according to a gate voltage (positive voltage) that is output from the gate control unit 2A through the gate line 11. Then, an X-ray image in accordance with the signal thus read out is generated in the control unit 2.

### Embodiment 2

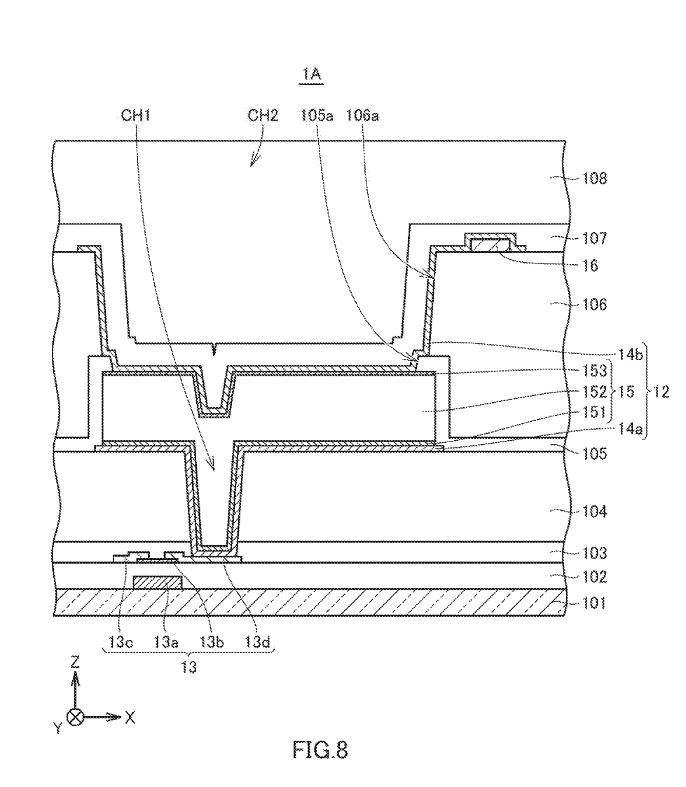

FIG. 8 is a cross-sectional view showing the structure of a pixel portion of an active matrix substrate in the present embodiment. In FIG. 8, the same constituent members as those in Embodiment 1 are denoted by the same reference symbols as those in Embodiment 1. The following description principally describes structures different from those in Embodiment 1.

As shown in FIG. 8, the active matrix substrate 1A in the present embodiment is different from that in Embodiment 1 in the point that the bias line 16 is arranged on the fourth insulating film 106, and the bias line 16 is covered with the upper electrode 14b.

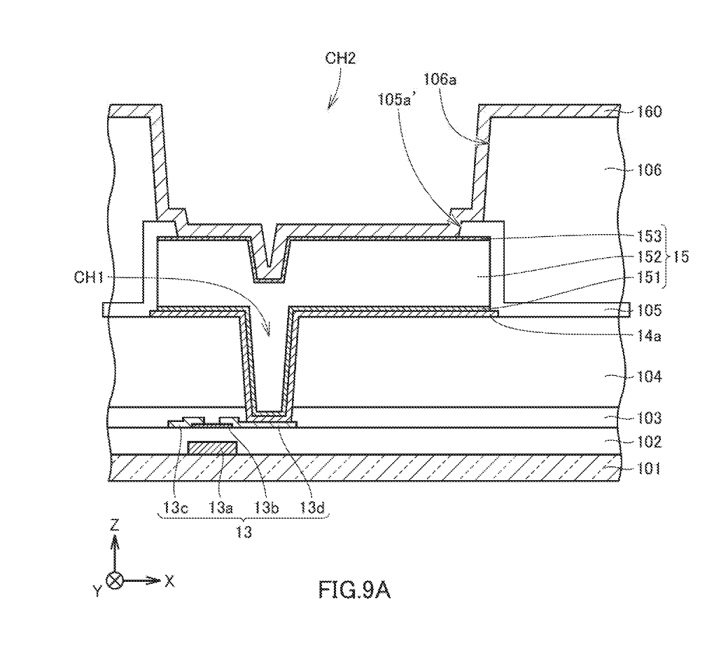

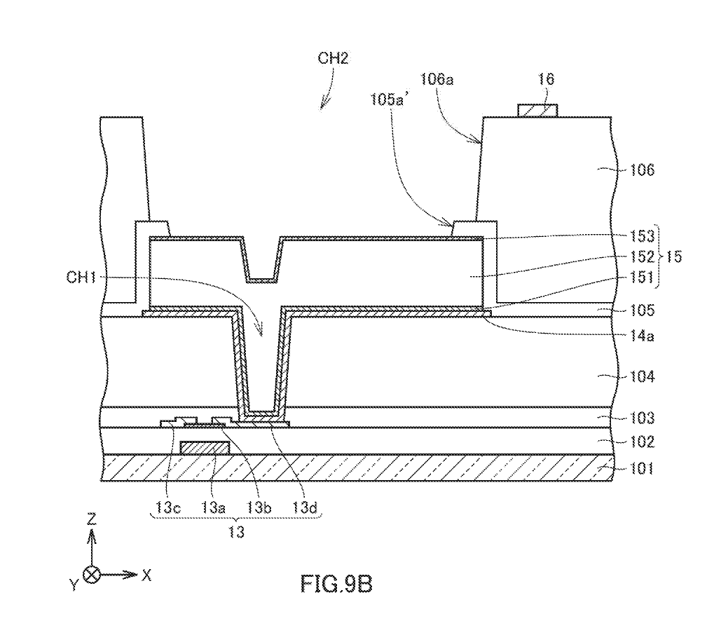

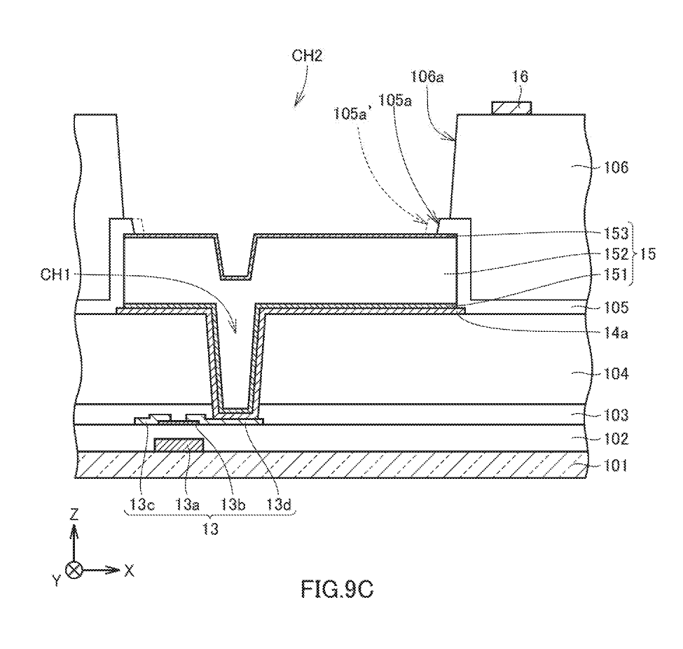

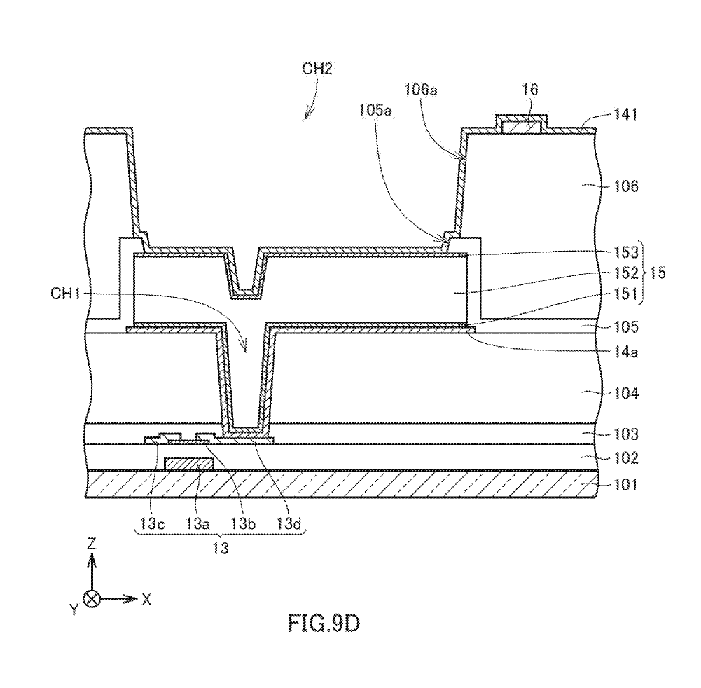

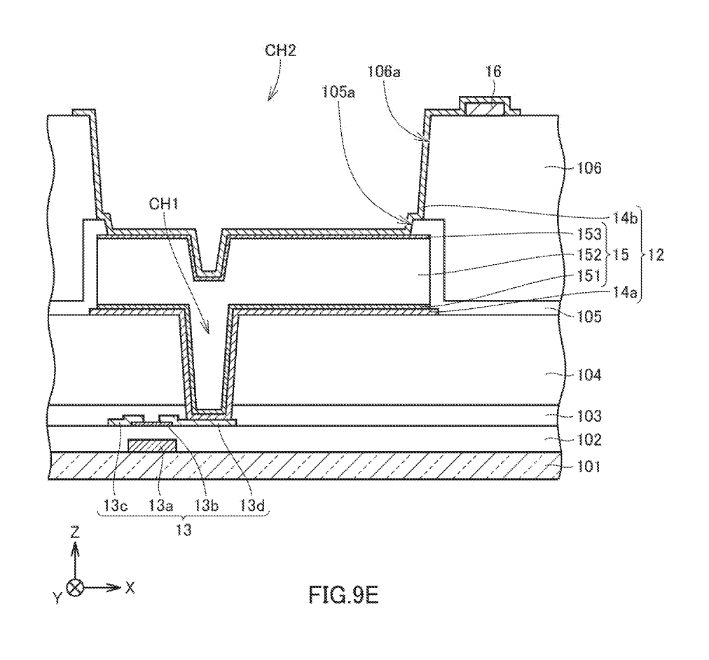

The method for producing the active matrix substrate 1A is as follows. First, the same steps as the respective steps described above with reference to FIGS. 6A to 6L are carried out, and thereafter, a metal film 160 is formed by laminating molybdenum nitride (MoN), aluminum (Al), and molybdenum nitride (MoN) sequentially in this order on the fourth insulating film 106 by using, for example, sputtering (see FIG. 9A).

Subsequently, photolithography and wet etching are carried out so as to pattern the metal film 160. Through these steps, the bias line 16 is formed on the fourth insulating film 106, on an outer side of the photoelectric conversion layer 15 (see FIG. 9B).

Next, a native oxide film adhering to the surface of the p-type amorphous semiconductor layer 153 is removed with use of hydrofluoric acid. Through these steps, the end portion of the third insulating film 105 is side-etched by hydrofluoric acid, whereby an opening 105a, which is greater than the opening 105a′, is formed (see FIG. 9C). As shown in FIG. 9C, even after the treatment with use of hydrofluoric acid, the position of the end portion of the third insulating film 105 is arranged on an inner side in the in-plane direction of the photoelectric conversion layer 15 with respect to the end portion of the fourth insulating film 106. In other words, the fourth insulating film 106 does not become overhung with respect to the third insulating film 105. Further, in this treatment with hydrofluoric acid, as is the case with Embodiment 1 described above, the p-type amorphous semiconductor layer 153 is eroded, while the native oxide film on the surface of the p-type amorphous semiconductor layer 153 is removed, whereby the thickness of the p-type amorphous semiconductor layer 153 in the opening 105a further decreases. In other words, as shown in FIG. 5, in the p-type amorphous semiconductor layer 153, the thickness ha of a portion thereof in the opening 105a is smaller than the thickness hb of a non-opening portion thereof with which the third insulating film 105 overlaps.

Then, the transparent conductive film 141 made of ITO is formed by using, for example, sputtering so as to cover the bias line 16 (see FIG. 9D). Subsequently, photolithography and dry etching are carried out so as to pattern the transparent conductive film 141. Through these steps, the upper electrode 14b in contact with the bias line 16 and the p-type amorphous semiconductor layer 153 is formed (see FIG. 9E). Thereafter, the same steps as the respective steps described above with reference to FIGS. 6 R, 6S are carried out, whereby the active matrix substrate 1A (see FIG. 8) is formed.

In Embodiment 2, when the upper electrode 14b is formed, the position of the end portion of the third insulating film 105 is arranged on an inner side in the in-plane direction of the photoelectric conversion layer 15 with respect to the end portion of the fourth insulating film 106, and the surface of the p-type amorphous semiconductor layer 153 is cleaned with use of hydrofluoric acid. This allows the upper electrode 14b to hardly have disconnections, and this makes it possible to stabilize the contact resistance between the upper electrode 14b and the p-type amorphous semiconductor layer 153

### Embodiment 3

In Embodiment 2 described above, the third insulating film 105 is etched with use of hydrofluoric acid when the opening 105a′ is formed, and the surface of the p-type amorphous semiconductor layer 153 is cleaned with use of hydrofluoric acid before the upper electrode 14b is formed. As the present embodiment, an exemplary case in which, in addition to the treatment with use of hydrofluoric acid, the surface of the p-type amorphous semiconductor layer 153 is cleaned also before the bias line 16 is formed, is described.

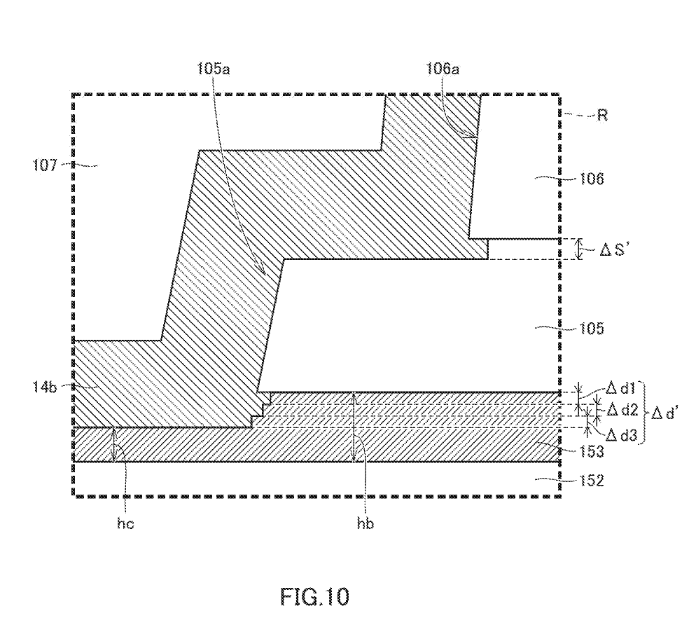

FIG. 10 is an enlarged cross-sectional view showing a part of the active matrix substrate shown in FIG. 8, the view explaining the thicknesses of the p-type amorphous semiconductor layer 153 and the third insulating film 105 in the present embodiment.

As shown in FIG. 10, regarding the thickness hc of a portion of the p-type amorphous semiconductor layer 153 in the opening 105a and the thickness hb of a non-opening portion of the same with which the third insulating film 105 overlaps (hc<hb), the thickness hc is smaller by Δd′ (Δd1+Δd2+Δd3) than the thickness hb. The thickness hc is smaller than the thickness ha of the p-type amorphous semiconductor layer 153 in Embodiments 1 and 2 (see FIG. 5). Further, in the third insulating film 105, the thickness of a portion thereof on the opening 105a side is Δs′ (for example, about 10 nm) smaller than that of the other portion so that the portion on the opening 105a side is positioned at Δs′ from the lower surface of the fourth insulating film 106.

As described above, in the present embodiment, the cleaning treatment with use of hydrofluoric acid is carried out twice with respect to the surface of the p-type amorphous semiconductor layer 153. This causes the thickness of the portion of the p-type amorphous semiconductor layer 153 in the opening 105a and the thickness of the end portion of the third insulating film 105 to decrease, as compared with Embodiments 1 and 2. In this way, the surface of the p-type amorphous semiconductor layer 153 is cleaned with use of hydrofluoric acid not only before the upper electrode 14b is formed, but also before the bias line 16 is formed, whereby the effect of cleaning the surface of the p-type amorphous semiconductor layer 153 is improved, and the contact resistance between the upper electrode 14b and the p-type amorphous semiconductor layer 153 is further stabilized.

The following description describes a method for producing the active matrix substrate in the present embodiment. The following description principally describes steps different from those in Embodiment 2.

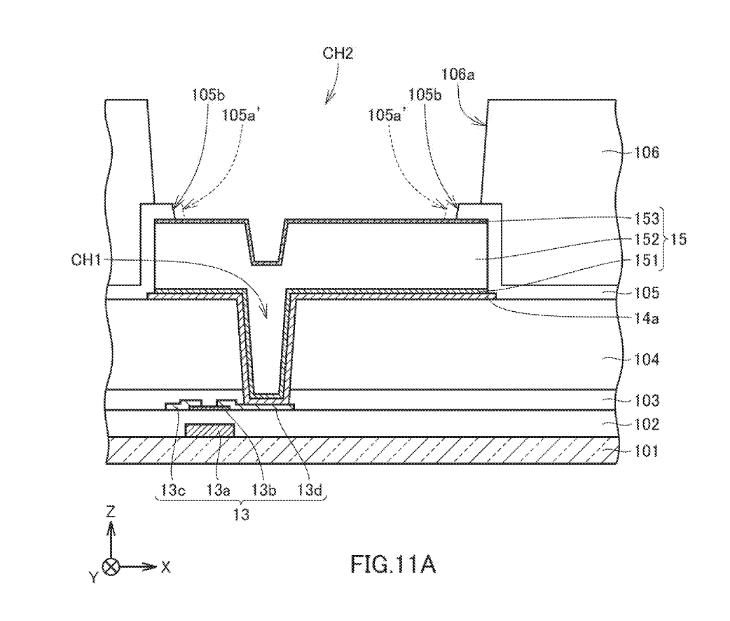

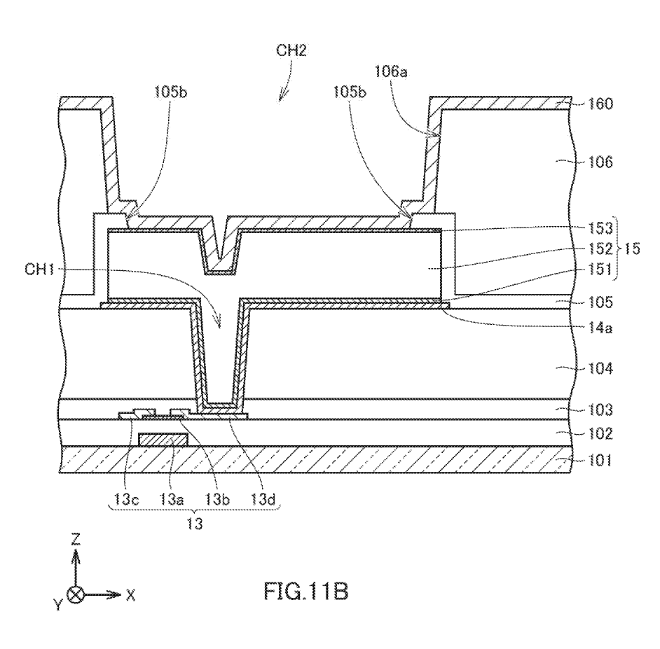

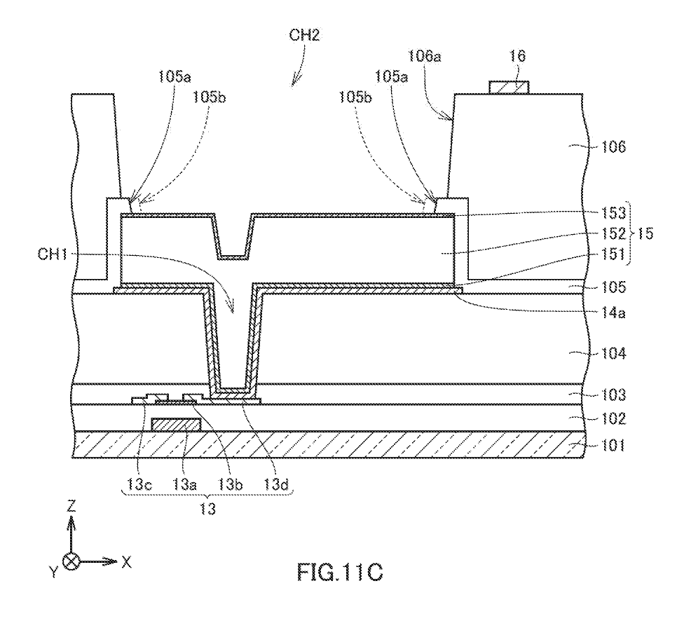

First, the same steps as the respective steps described above with reference to FIGS. 6A to 6L are carried out, whereby the opening 106a of the fourth insulating film 106 is formed, and thereafter, the same step as that described above with reference to FIG. 6M is carried out. More specifically, the surface of the p-type amorphous semiconductor layer 153 is cleaned with use of hydrofluoric acid, whereby a native oxide film adhering to the surface of the p-type amorphous semiconductor layer 153 is removed. Through these steps, the end portion of the third insulating film 105 is etched with hydrofluoric acid, whereby an opening 105b having an opening width greater than that of the opening 105a′ of the third insulating film 105 is formed (see FIG. 11A).

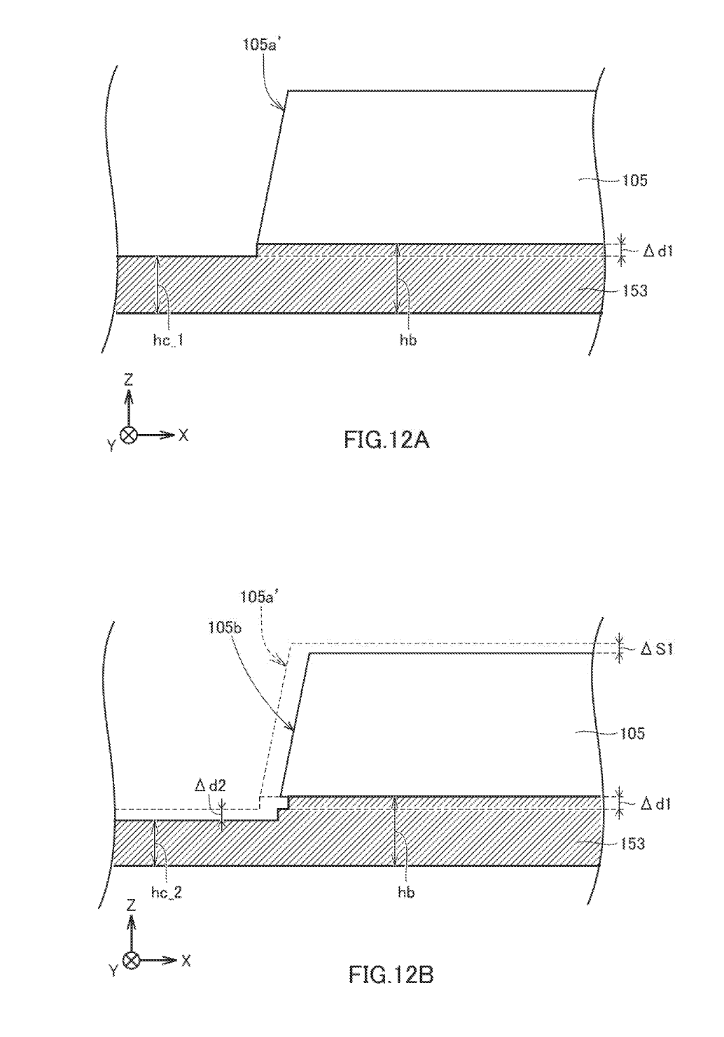

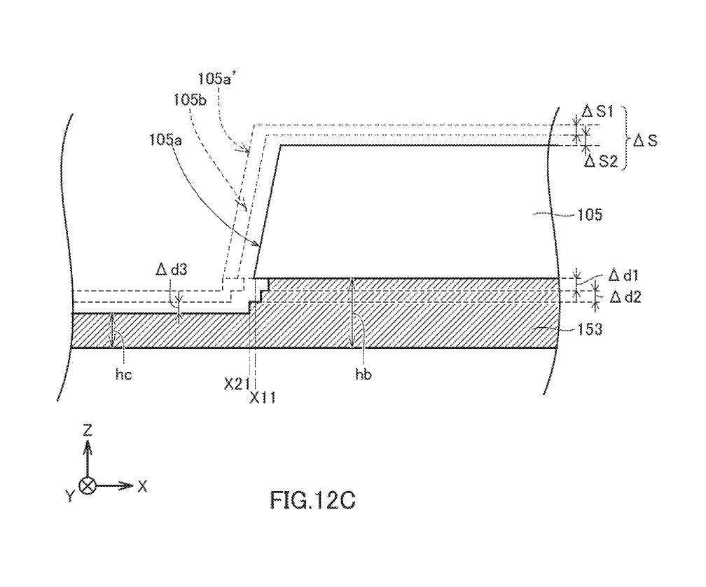

The cleaning treatment shown in FIG. 11A is the second round of the treatment with use of hydrofluoric acid. In other words, the first round of the treatment with use of hydrofluoric acid is the above-described step shown in FIG. 6J (the step of forming the opening 105a of the third insulating film 105), and the cleaning treatment shown in FIG. 11A is the second round of the treatment with use of hydrofluoric acid. The second round of the treatment with use of hydrofluoric acid causes the third insulating film 105 and the p-type amorphous semiconductor layer 153 to have smaller thicknesses as compared with the thicknesses when these films are formed. FIG. 12A is an enlarged cross-sectional view showing the p-type amorphous semiconductor layer 153 and the third insulating film 105 after the first round of the treatment with use of hydrofluoric acid (the step shown in FIG. 6J), FIG. 12B is an enlarged cross-sectional view showing the p-type amorphous semiconductor layer 153 and the third insulating film 105 after the second round of the treatment with use of hydrofluoric acid (see FIG. 11A).

As shown in FIG. 12A, by the etching step shown in FIG. 6J, the opening 105a′ of the third insulating film 105 is formed, and the thickness hc_1 of the p-type amorphous semiconductor layer 153 in the opening 105a′ is smaller by Δd1 than the thickness hb of the p-type amorphous semiconductor layer 153 covered with the third insulating film 105.

Thereafter, by the cleaning step shown in FIG. 11A, the surfaces of the third insulating film 105 that are not covered with the fourth insulating film 106 and the p-type amorphous semiconductor layer 153 are etched. As a result, as shown in FIG. 12B, the third insulating film 105 not covered with the fourth insulating film 106 becomes Δs1 (for example, about 5 nm) thinner, and is side-etched, whereby the opening 105b, having an opening width greater than that of the opening 105a′, is formed. Further, the portion of the p-type amorphous semiconductor layer 153 that is not covered with the third insulating film 105 has a thickness hc_2 that is further Δd2 smaller than the thickness hc_1 (see FIG. 12A), whereby the p-type amorphous semiconductor layer 153 has a step portion thus formed.

After the step shown in FIG. 11A, the metal film 160 is formed by laminating molybdenum nitride (MoN), aluminum (Al), and molybdenum nitride (MoN) sequentially in this order by using, for example, sputtering (see FIG. 11B).

Then, photolithography and wet etching are carried out so as to pattern the metal film 160, and thereafter, the surface of the p-type amorphous semiconductor layer 153 is cleaned with use of hydrofluoric acid (see FIG. 11C). Through these steps, as shown in FIG. 11C, the bias line 16 is formed on the fourth insulating film 106, on an outer side of the photoelectric conversion layer 15. Further, by the cleaning treatment with use of hydrofluoric acid, the surfaces of the third insulating film 105 and the p-type amorphous semiconductor layer 153 are etched. Through these steps, an opening 105a, which is greater than the opening 105b, is formed, but the position of the end portion of the third insulating film 105 is arranged on an inner side in the in-plane direction of the photoelectric conversion layer 15 with respect to the end portion of the fourth insulating film 106. In other words, the fourth insulating film 106 does not become overhung with respect to the third insulating film 105.

The cleaning step shown in FIG. 11C is the third round of the treatment with use of hydrofluoric acid. FIG. 12C is an enlarged cross-sectional view showing the p-type amorphous semiconductor layer 153 and the third insulating film 105 after the third round of the treatment with use of hydrofluoric acid. As shown in FIG. 12C, by the third round of the treatment with use of hydrofluoric acid, the opening-105b-side end portion of the third insulating film 105 becomes further Δs2 (for example, about 5 nm) thinner, and is side-etched. Through these steps, the opening 105a, having an opening width greater than that of the opening 105b. The portion of the p-type amorphous semiconductor layer 153 that is not covered with the third insulating film 105 has a thickness hc that is further Δd3 smaller than the thickness hc_2 (see FIG. 12B), and the p-type amorphous semiconductor layer 153 under the third insulating film 105 is further etched toward the inner side of the third insulating film 105.

Incidentally, in this example, the position X11 of an end portion of the third insulating film 105 is arranged on an outer side of the photoelectric conversion layer 15 with respect to the position X21 of the lowermost step portion of the p-type amorphous semiconductor layer 153, since the rate of etching with respect to the third insulating film 105 is greater than that with respect to the p-type amorphous semiconductor layer 153. The etching conditions, however, may be set so that the etching rate with respect to the third insulating film 105 is greater. In this case, the p-type amorphous semiconductor layer 153 under the third insulating film 105 is etched toward the inner side of the third insulating film 105, whereby the third insulating film 105 becomes overhung with respect to the position X21 of the step portion of the p-type amorphous semiconductor layer 153.

Thereafter, the same steps as the respective above-described steps shown in FIGS. 9D, 9E are carried out so as to form the upper electrode 14b, and subsequently, the same steps as the respective above-described steps shown in FIGS. 6R, 6S are carried out.

Embodiments of the present invention are described above, but the above-described embodiments are merely examples for implementing the present invention. The present invention, therefore, is not limited to the above-described embodiments, and the above-described embodiments can be appropriately varied and implemented without departing from the spirit and scope of the invention. The following description describes modification examples.

(1) The method for producing the active matrix substrate of Embodiment 1 described above is not limited to the method described above. The following description describes a producing method different from that of Embodiment 1.

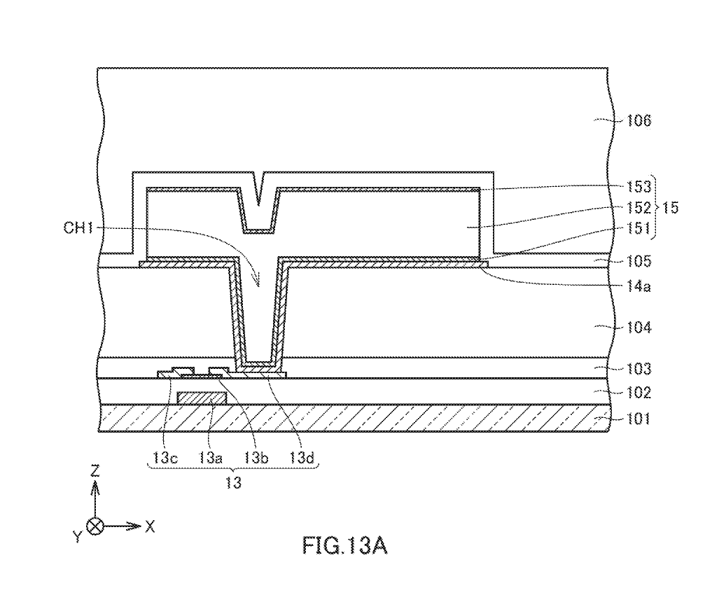

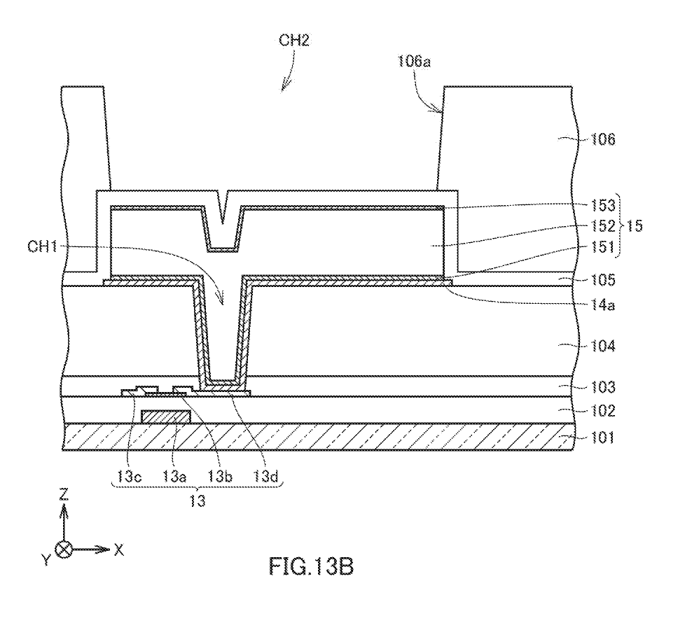

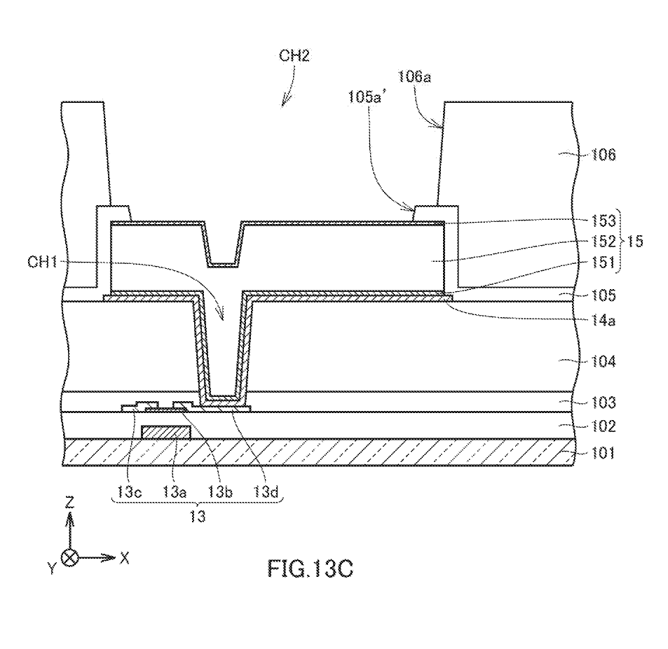

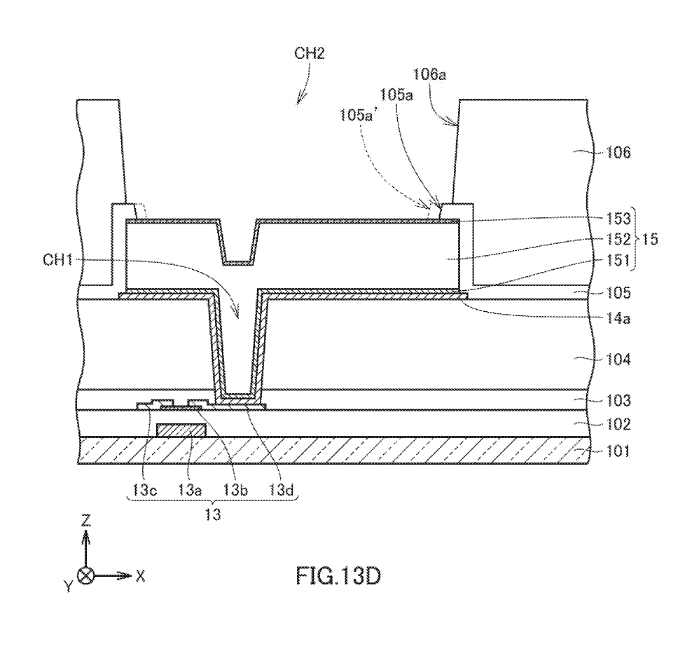

In Embodiment 1, in the step shown in FIG. 6I, the opening 105a of the third insulating film 105 is formed after the third insulating film 105 is formed; in the present modification example, however, after the step shown in FIG. 6I, the fourth insulating film 106 made of acrylic resin or siloxane-based resin is formed, by using, for example, slit-coating so as to cover the third insulating film 105 (see FIG. 13A).

Thereafter, photolithography and wet etching are carried out so that the opening 106a of the fourth insulating film 106 is formed on the photoelectric conversion layer 15 (see FIG. 13B).

Subsequently, photolithography and wet etching are carried out so as to pattern the third insulating film 105, whereby the opening 105a′ of the third insulating film 105, having an opening width smaller than that of the opening 106a of the fourth insulating film 106, is formed on the photoelectric conversion layer 15 (see FIG. 13C). Here, as an etchant of the wet etching, hydrofluoric acid may be used.

Next, the surface of the p-type amorphous semiconductor layer 153 is cleaned with use of hydrofluoric acid. Through these steps, the end portion of the third insulating film 105 is etched with hydrofluoric acid, whereby the opening 105a, having an opening width greater than that of the opening 105a′, is formed (see FIG. 13D). Incidentally, even if the end portion of the third insulating film 105 is etched with hydrofluoric acid, the end portion of the third insulating film 105 is arranged on an inner side in the in-plane direction of the photoelectric conversion layer 15 with respect to the end portion of the fourth insulating film 106, as shown in FIG. 13D. Further, through the two rounds of the treatment with hydrofluoric acid in the steps shown in FIGS. 13C and 13D, the portion in the opening 105a of the p-type amorphous semiconductor layer 153 has a thickness that is Δd (see FIG. 5) smaller than the thickness of the non-opening portion thereof with which the third insulating film 105 overlaps.

Thereafter, by carrying out the same steps as the above-described respective steps shown in FIGS. 6N to 6S, the active matrix substrate 1 shown in FIG. 4 is produced.

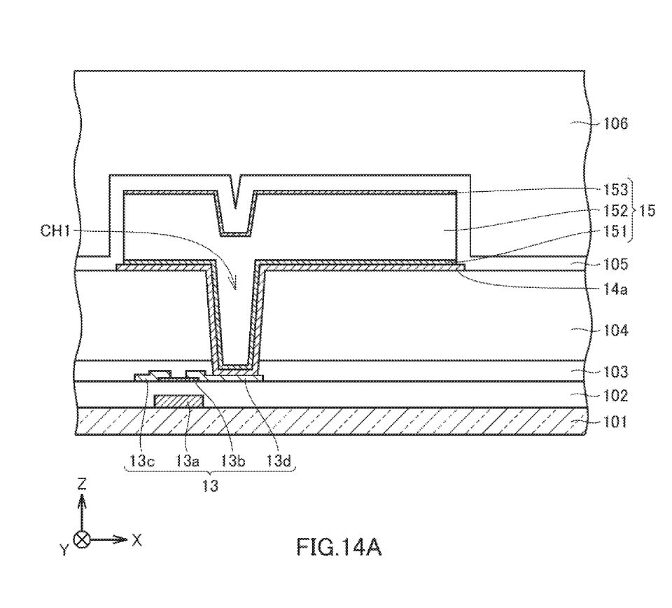

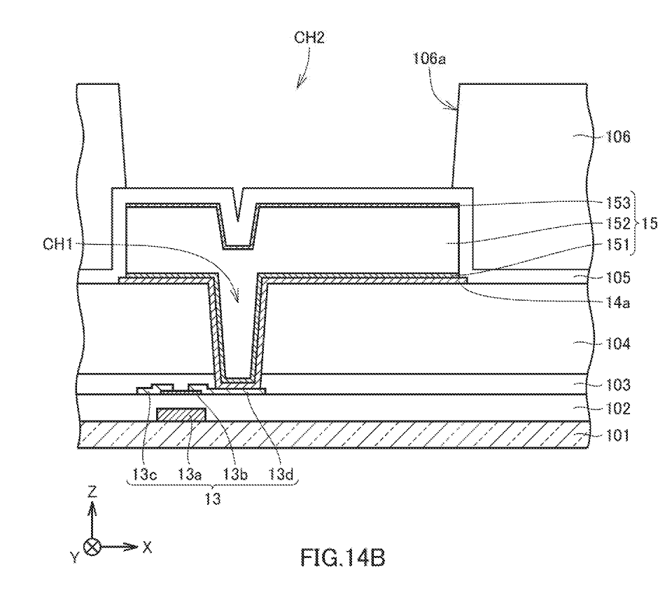

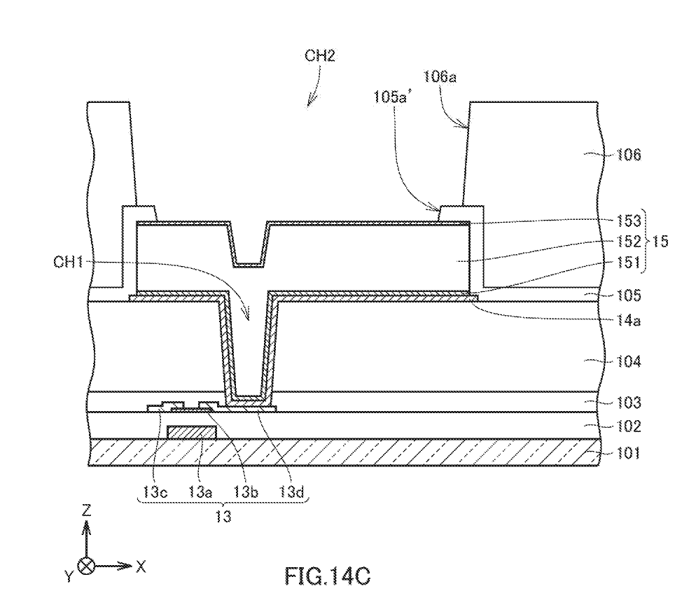

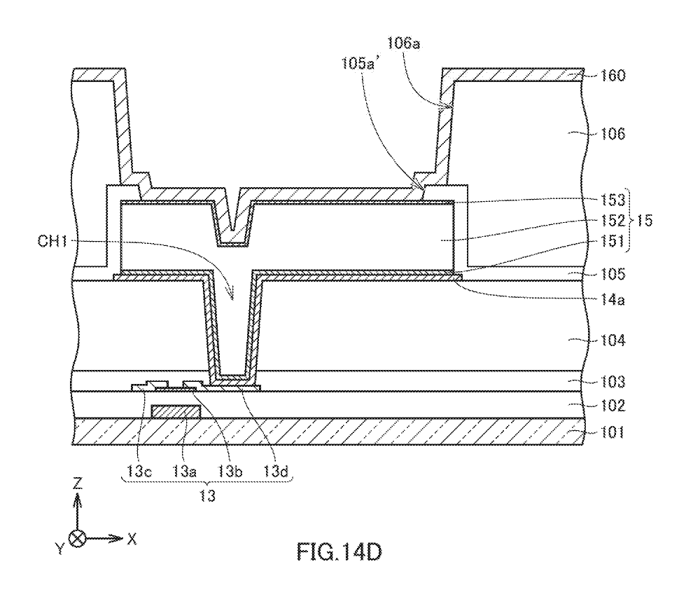

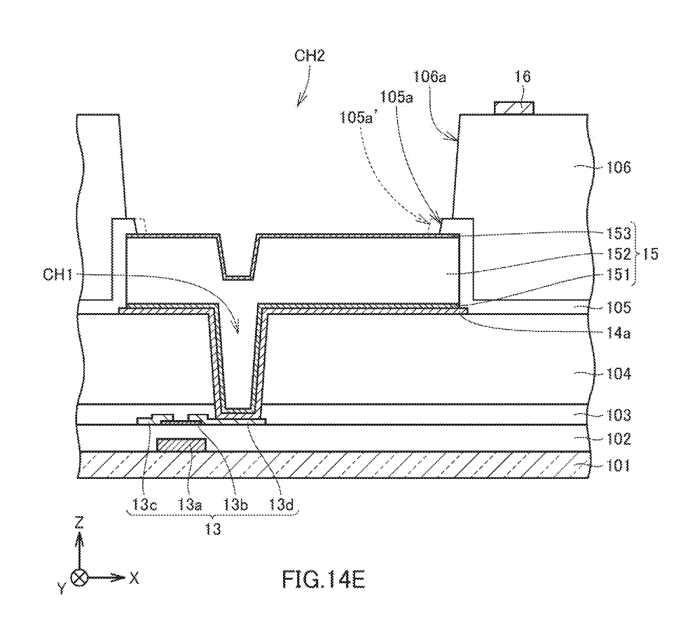

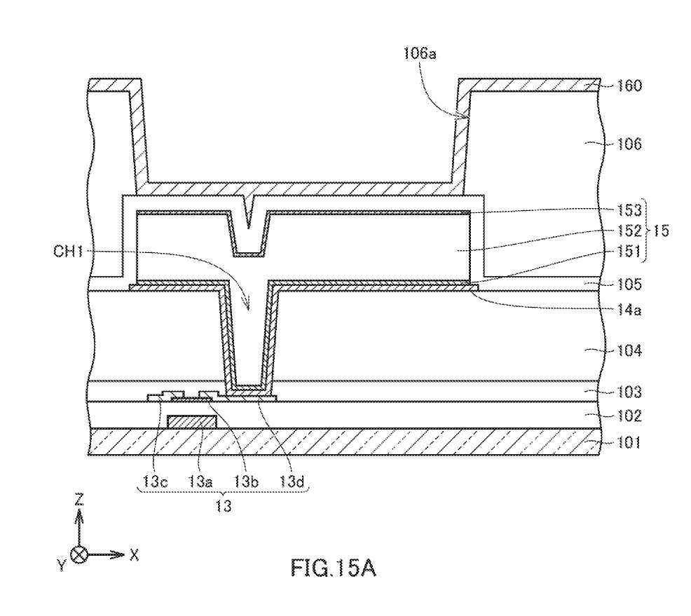

(2) Further, in Embodiment 2 described above, after the third insulating film 105 is formed in the step shown in FIG. 6I, the opening 105a of the third insulating film 105 is formed; but in the present modification example, after the step shown in FIG. 6I, the fourth insulating film 106 made of acrylic resin or siloxane-based resin is formed by using, for example, slit-coating so as to cover the third insulating film 105 (see FIG. 14A). Thereafter, photolithography and wet etching are carried out so as to form the opening 106a of the fourth insulating film 106 on the photoelectric conversion layer 15 (see FIG. 14B).

Subsequently, photolithography and wet etching are carried out so as to pattern the third insulating film 105, whereby the opening 105a′ of the third insulating film 105, having an opening width smaller than that of the opening 106a of the fourth insulating film 106, is formed on the photoelectric conversion layer 15 (see FIG. 14C).

Thereafter, for example, the metal film 160 is formed by laminating molybdenum nitride (MoN), aluminum (Al), and molybdenum nitride (MoN) sequentially in this order by using sputtering (see FIG. 14D).

Then, photolithography and wet etching are carried out so as to pattern the metal film 160, thereby forming the bias line 16, and thereafter, the surface of the p-type amorphous semiconductor layer 153 is cleaned with use of hydrofluoric acid (see FIG. 14E). Through these steps, the end portion of the third insulating film 105 is etched, whereby the opening 105a, having an opening width greater than that of the opening 105a′, is formed.

Subsequently, the same steps as the above-described respective steps shown in FIGS. 9D to 9E are carried out, whereby the upper electrode 14b is formed. In this case as well, the surface of the p-type amorphous semiconductor layer 153 is cleaned before the upper electrode 14b is formed, but after the cleaning treatment, the fourth insulating film 106 does not become overhung with respect to the third insulating film 105. This makes it unlikely that the upper electrode 14b would have disconnections at the step portions of the third insulating film 105 and the fourth insulating film 106, thereby allowing the contact resistance between the upper electrode 14b and the p-type amorphous semiconductor layer 153 to be stabilized. After the upper electrode 14b is formed, the same steps as the above-described respective steps illustrate in FIGS. 6R to 6S are carried out, whereby the active matrix substrate 1A (see FIG. 8) can be formed.

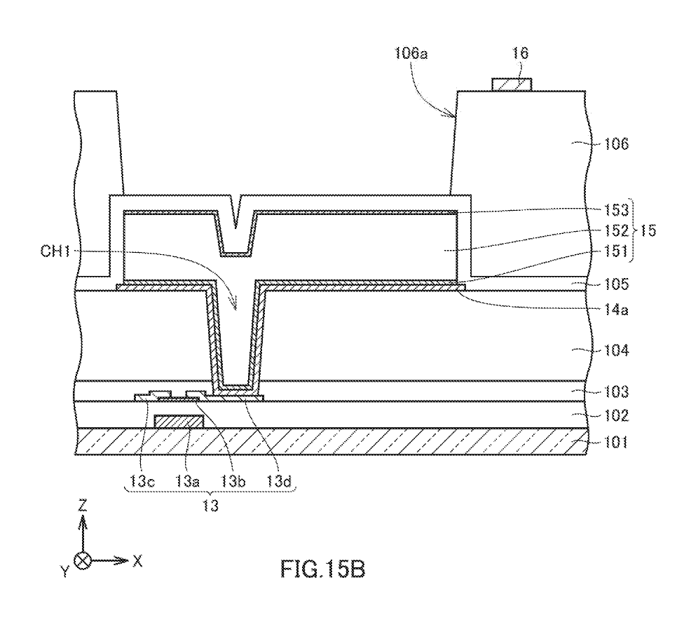

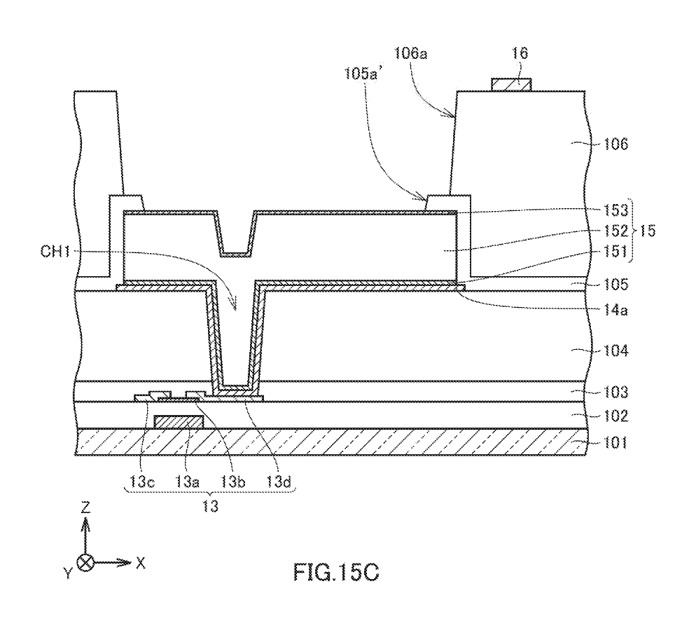

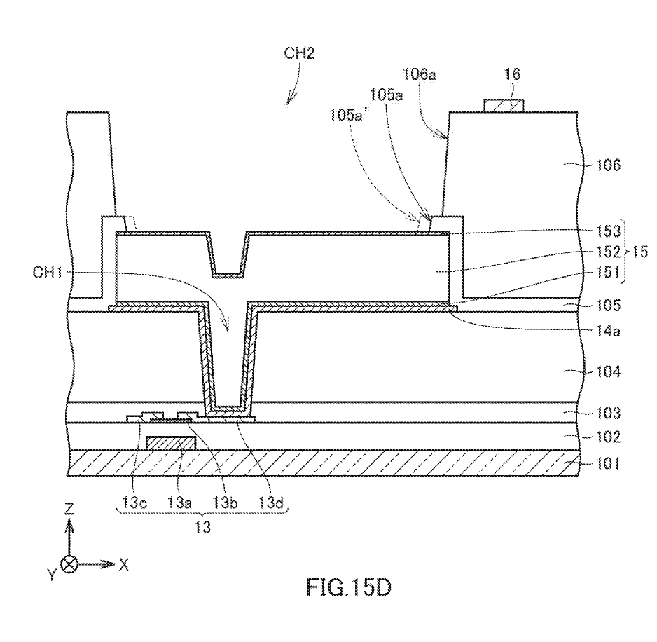

(3) In Modification Example (2) described above, in the step of shown in FIG. 14B, the opening 106a of the fourth insulating film 106 is formed, and thereafter, in the step shown in FIG. 14C, the opening 105a′ of the third insulating film 105 is formed. In the present modification example, after the step shown in FIG. 14B, the metal film 160 is formed by laminating molybdenum nitride (MoN), aluminum (Al), and molybdenum nitride (MoN) sequentially in this order by using, for example, sputtering (see FIG. 15A). Then, photolithography and wet etching are carried out so as to pattern the metal film 160. Through these steps, on the fourth insulating film 106, on an outer side with respect to the photoelectric conversion layer 15, the bias line 16 is formed (see FIG. 15B).

Subsequently, photolithography and wet etching are carried out so as to pattern the third insulating film 105, the opening 105a′ of the third insulating film 105, having an opening width smaller than that of the opening 106a of the fourth insulating film 106, is formed on the photoelectric conversion layer 15 (see FIG. 15C). In this wet etching, hydrofluoric acid is used as an etchant.

Thereafter, the surface of the p-type amorphous semiconductor layer 153 is cleaned with use of hydrofluoric acid. Through these steps, the end portion of the third insulating film 105 is etched with hydrofluoric acid, whereby the opening 105a, having an opening width greater than that of the opening 105a′, is formed (see FIG. 15D).

Thereafter, the same steps as the respective steps described above with reference to FIGS. 9D to 9E are carried out, whereby the upper electrode 14b is formed. In this case as well, the surface of the p-type amorphous semiconductor layer 153 is cleaned before the upper electrode 14b is formed, but after the cleaning treatment, the fourth insulating film 106 does not become overhung with respect to the third insulating film 105. This makes it unlikely that the upper electrode 14b would have disconnections at the step portions of the third insulating film 105 and the fourth insulating film 106, thereby allowing the contact resistance between the upper electrode 14b and the p-type amorphous semiconductor layer 153 to be stabilized.

After the upper electrode 14b is formed, the same steps as the above-described respective steps shown in FIGS. 6R to 6S are carried out, whereby the active matrix substrate 1A (see FIG. 8) can be formed.

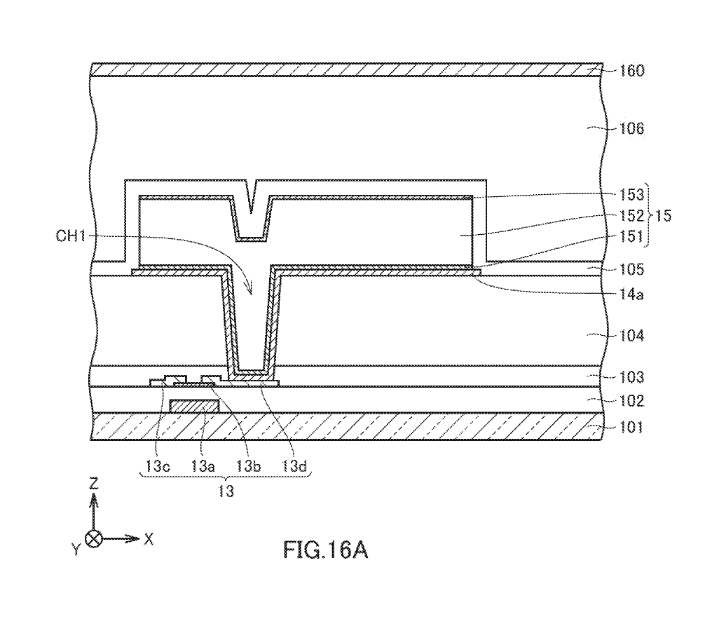

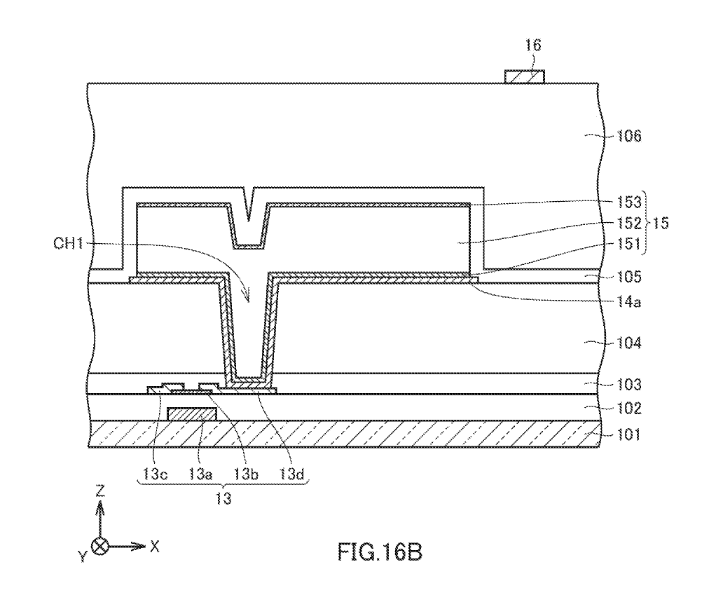

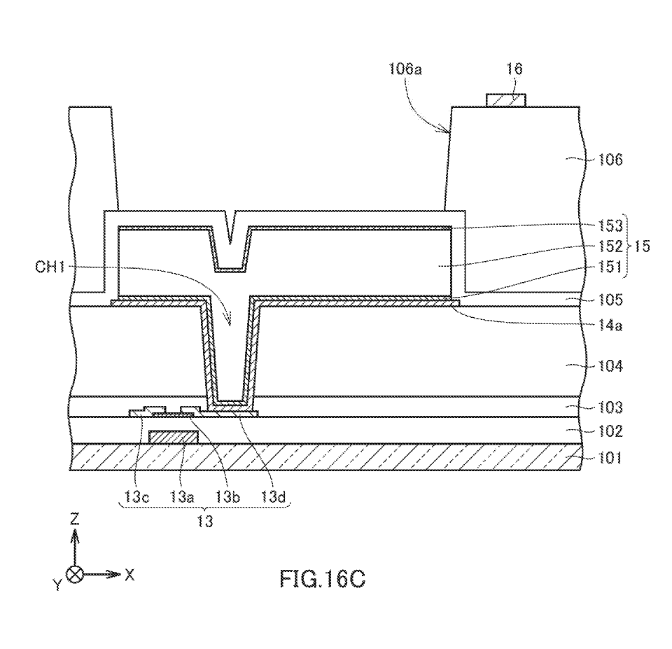

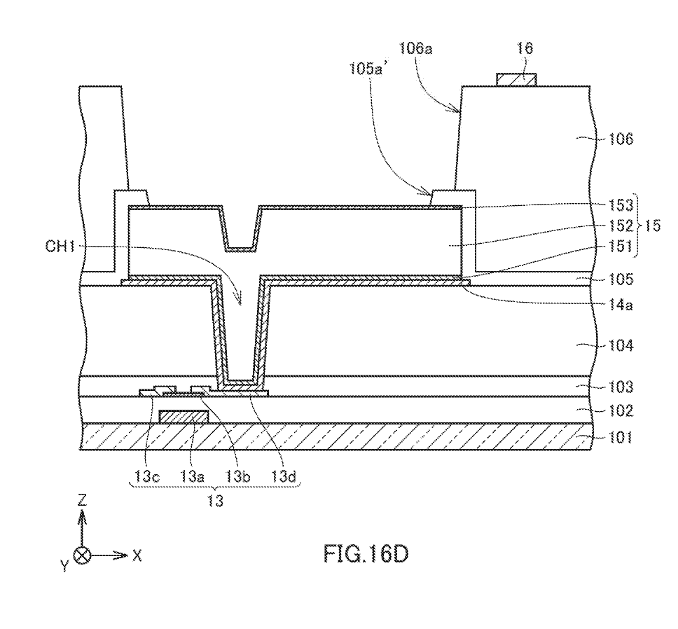

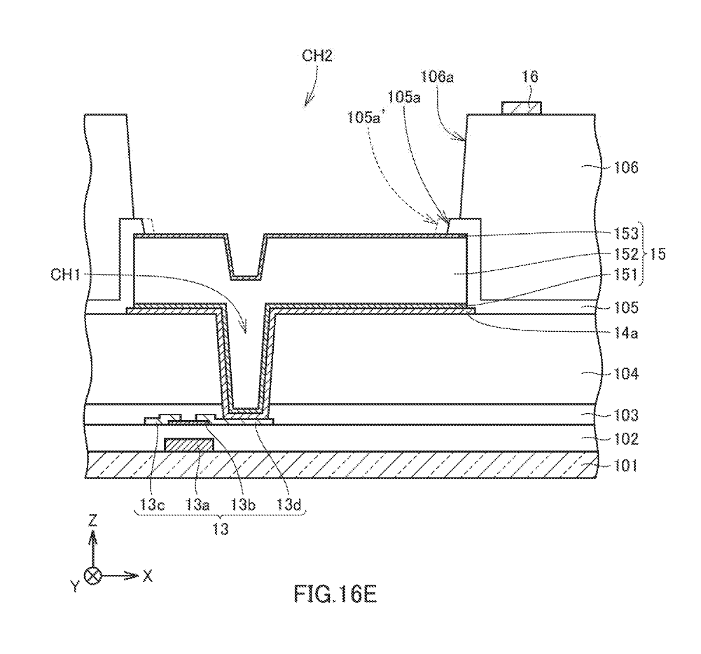

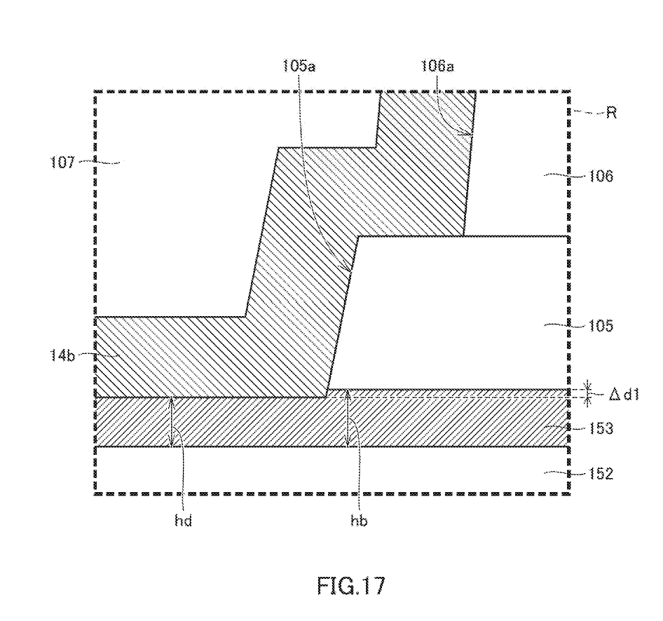

(4) In Modification Example (2) described above, after the step shown in FIG. 14A, the opening 106a of the fourth insulating film 106 is formed. In the present modification example, after the step shown in FIG. 14A, the metal film 160 is formed by laminating molybdenum nitride (MoN), aluminum (Al), and molybdenum nitride (MoN) sequentially in this order on the fourth insulating film 106 by using, for example, sputtering (see FIG. 16A). Then, photolithography and wet etching are carried out so as to pattern the metal film 160. Through these steps, on the fourth insulating film 106, on an outer side with respect to the photoelectric conversion layer 15, the bias line 16 is formed (see FIG. 16B).

Subsequently, photolithography method and wet etching are carried out so that the opening 106a of the fourth insulating film 106 is formed (see FIG. 16C), and thereafter, photolithography and wet etching are carried out so that the opening 105a′ of the third insulating film 105 is formed on an inner side with respect to the opening 106a of the fourth insulating film 106 (see FIG. 16D). When the opening 105a′ of the third insulating film 105 is formed, hydrofluoric acid is used as an etchant.

Thereafter, the surface of the p-type amorphous semiconductor layer 153 is cleaned with use of hydrofluoric acid. Through these steps, the end portion of the third insulating film 105 is etched with hydrofluoric acid, whereby the opening 105a, having an opening width greater than that of the opening 105a′, is formed (see FIG. 16E).

Thereafter, the same steps as the respective steps described above with reference to FIGS. 9D to 9E are carried out, whereby the upper electrode 14b is formed. In this case as well, the surface of the p-type amorphous semiconductor layer 153 is cleaned before the upper electrode 14b is formed, but after the cleaning treatment, the fourth insulating film 106 does not become overhung with respect to the third insulating film 105. This makes it unlikely that the upper electrode 14b would have disconnections at the step portions of the third insulating film 105 and the fourth insulating film 106, thereby allowing the contact resistance between the upper electrode 14b and the p-type amorphous semiconductor layer 153 to be stabilized. After the upper electrode 14b is formed, the same steps as the above-described respective steps illustrate in FIGS. 6R to 6S are carried out, whereby the active matrix substrate 1A (see FIG. 8) can be formed.

(5) In the producing methods in Embodiment 1 and Embodiment 2, the cleaning treatment with use of hydrofluoric acid is carried out before the upper electrode 14b is formed, but the cleaning step with use of hydrofluoric acid may be omitted. In other words, the method may be such that the etching with use of hydrofluoric acid is carried out only when at least the opening 105a′ of the third insulating film 105 is formed.

In this case, the p-type amorphous semiconductor layer 153 is exposed to hydrofluoric acid exclusively when the third insulating film 105 is etched. As shown in FIG. 17, therefore, the p-type amorphous semiconductor layer 153 in the opening 105a of the third insulating film 105 has a thickness hd that is Δd1 smaller than the thickness hb of the non-opening portion of the p-type amorphous semiconductor layer 153 with which the third insulating film 105 overlaps. In this case, the number of times when the surface of the p-type amorphous semiconductor layer 153 is exposed to hydrofluoric acid is smaller than those in Embodiments 1 to 3 described above, whereby the p-type amorphous semiconductor layer 153 has a thickness hd that is greater than the thickness ha of the p-type amorphous semiconductor layer 153 in Embodiments 1 to 3 (see FIGS. 5 and 10).

Incidentally, in a case where the etching conditions are set so that the etching rate with respect to the third insulating film 105 is greater than that with respect to the etching p-type amorphous semiconductor layer 153 in the present example, the p-type amorphous semiconductor layer 153 under the third insulating film 105 is etched toward an inner side of the third insulating film 105, whereby the third insulating film 105 becomes overhung with respect to the p-type amorphous semiconductor layer 153.

### CROSS REFERENCE TO RELATED APPLICATION

The present application claims priority under 35 U.S.C. § 119 to Japanese Patent Application No. 2018-026462, filed Feb. 16, 2018. The contents of this application are incorporated herein by reference in their entirety.

1. An active matrix substrate having a plurality of detection circuitry are arranged in matrix,
each of the detection circuitry includes:
a photoelectric conversion layer;
a first electrode provided on a first surface of the photoelectric conversion layer;
a second electrode provided on a second surface of the photoelectric conversion layer, the second surface being on a side opposite to the side of the first surface;
a first insulating film that covers an end portion of the second surface and a side surface of the photoelectric conversion layer, and has a first opening on the second surface; and
a second insulating film that overlaps with the first insulating film, and has a second opening that has an opening width greater than that of the first opening, the second opening being on the second surface,
wherein the second electrode is in contact with the second surface in the first opening, and is in contact with the first insulating film and the second insulating film.

2. The active matrix substrate according to claim 1,
wherein a portion of the photoelectric conversion layer in the first opening has a thickness that is smaller than that of a portion of the photoelectric conversion layer on which the first insulating film overlaps.

3. The active matrix substrate according to claim 1,
wherein the photoelectric conversion layer includes a first semiconductor layer having a first conductive type, a second semiconductor layer having a second conductive type that is opposite to the first conductive type, and an intrinsic amorphous semiconductor layer provided between the first semiconductor layer and the second semiconductor layer,
the first semiconductor layer is in contact with the first electrode, and
the second semiconductor layer is in contact with the second electrode and the first insulating film, wherein a portion of the second semiconductor layer in the first opening has a thickness smaller than that of a portion of the second semiconductor layer with which the first insulating film overlaps.

4. The active matrix substrate according to claim 1,
wherein a portion on the first opening side of the first insulating film has a thickness smaller than that of a portion of the first insulating film that overlaps with the second insulating film.

5. An imaging panel comprising:
the active matrix substrate according to claim 1; and
a scintillator that convers irradiated X-rays into scintillation light.

6. A method for producing an active matrix substrate that includes a plurality of detection circuitry arranged in matrix, the producing method comprising the steps of, in each of areas where the detection circuitry on the substrate are provided, respectively:
forming a first electrode;
forming a photoelectric conversion layer on the first electrode;
forming a first insulating film that covers an end portion of a second surface and a side surface of the photoelectric conversion layer, and has a first opening on the second surface, the second surface being on a side opposite to a first surface of the photoelectric conversion layer which the first electrode is in contact with;
forming a second insulating film that overlaps with the first insulating film, and has a second opening on the second surface, the second opening having an opening width greater than that of the first opening; and
forming a second electrode that is in contact with the second surface in the first opening, and is in contact with the first insulating film and the second insulating film.

7. The producing method according to claim 6,
wherein, in the step of forming the first insulating film, the first insulating film is etched with use of hydrofluoric acid s3o as to form the first opening, and
a portion of the photoelectric conversion layer in the first opening has a thickness smaller than that of a portion of the photoelectric conversion layer with which the first insulating film overlaps.

8. The producing method according to claim 6, further comprising the step of:
cleaning the second surface in the first opening with use of hydrofluoric acid, after the first insulating film is formed, before the second electrode is formed.

9. The producing method according to claim 6, further comprising the steps of:
forming a bias line that overlaps with the second electrode, on the second insulating film on an outer side with respect to the photoelectric conversion layer; and
cleaning the second surface in the first opening with use of hydrofluoric acid, before the second electrode and the bias line are formed.

10. The producing method according to claim 7, further comprising the step of:
cleaning the second surface in the first opening with use of hydrofluoric acid, after the first insulating film is formed, before the second electrode is formed.
